(19) United States
(12) Patent Application Publication
(10) Pub. No.: US 2024/0417858 A1
(43) Pub. Date: Dec. 19, 2024

(54) GENERATION OF AN ACTIVE OXYGEN SPECIES

(71) Applicant: Silanna UV Technologies Pte Ltd, Singapore (SG)

(72) Inventor: Petar Atanackovic, Henley Beach South (AU)

(73) Assignee: Silanna UV Technologies Pte Ltd, Singapore (SG)

(21) Appl. No.: 18/740,071

(22) Filed: Jun. 11, 2024

Related U.S. Application Data
(60) Provisional application No. 63/508,068, filed on Jun. 14, 2023.

(51) Int. Cl. C23C 16/48; C23C 16/44; C23C 16/455

(52) U.S. Cl. CPC C23C 16/482; C23C 16/4412; C23C 16/45557

(57) ABSTRACT

Methods and systems are disclosed for generating an active oxygen species. A photoreactor has a reaction chamber, where an inlet to the reaction chamber is configured to be coupled to an oxygen source that contains molecular oxygen. An optical excitation source is optically coupled to the reaction chamber and is configured to generate radiation in an ultraviolet wavelength range. The radiation excites a proportion of the molecular oxygen in the reaction chamber, without the use of a plasma generator, to form atomic oxygen such that the atomic oxygen is able to react with the molecular oxygen in the reaction chamber to form ozone. An outlet from the reaction chamber is configured to emit a gas mixture comprising the atomic oxygen, the molecular oxygen, and the ozone.

### RELATED APPLICATIONS

This application claims priority to U.S. Provisional Patent Application No. 63/508,068, filed on Jun. 14, 2023, and entitled “Generation of Active Oxygen Species”; the contents of which are hereby incorporated by reference in full.

### BACKGROUND

Various materials deposition processes, such as those for fabricating semiconductor materials, rely on the generation of precursor materials which together form a layer of a desired chemical compound when combined at a deposition surface. For the deposition of oxide layers, traditionally a first source provides the non-oxide component in vapour form and the other source provides one or more active oxygen species (e.g., oxygen plasma, ozone, atomic oxygen) able to donate single oxygen atoms to form the oxide layer at the deposition surface. Additional sources of non-oxide components may be used when forming more complicated oxides.

In one example, an active oxygen specie in the form of ozone may be formed using a dielectric-barrier discharge (DBD) ozone generator where molecular oxygen is processed to form ozone using a series of electrostatic plates to which a high voltage (e.g., 10 kV) has been applied to. In this example, molecular oxygen will dissociate into atomic oxygen due to electron bombardment (i.e., O₂+e⁻→2O*). Ozone is then formed by the reaction of molecular oxygen with atomic oxygen (i.e., O₂+O*→O₃). Unfortunately, this DBD process is only capable of generating an ozone-oxygen mixture having an ozone concentration of the order of 1%. In order to obtain a workable ozone concentration for use in deposition processes it is then necessary to further process the output from the DBD ozone generator via cryogenic distillation. This process is carried out at an approximate temperature of 4 K to form liquid ozone at a concentration of approximately 90% which is then cryogenically stored. To then obtain ozone for a deposition process, an amount of stored liquid ozone is “boiled” off.

In another example of a system for generating an active oxygen specie in the form of atomic oxygen, molecular oxygen at a selected flow rate is introduced by an inlet into a vacuum chamber also having an outlet. A radiofrequency (RF) microwave field is applied to the contents of the vacuum chamber to form a plasma and generate the atomic oxygen from the molecular oxygen. Generally, the inlet and outlet of the microwave vacuum chamber outlet will be configured to generate atomic oxygen at an outlet pressure from 1×10⁻⁶ Torr to 100×10⁻⁶ Torr which will be suitable for deposition purposes. These plasma-based processes typically have an efficiency of about 1% to 5% of atomic oxygen being produced.

In a further example of existing systems, a deposition system forms an oxide thin film by reacting with a surface of a substrate. In this example, oxygen gas is introduced in a chamber, and the oxygen gas is ionized on the surface of the substrate (e.g., silicon) using an ultraviolet lamp. A separate laser source is used to raise the temperature of the substrate to manufacture the thin film (e.g., silicon oxide).

### SUMMARY

In some aspects, a system for generating an active oxygen species has a reaction chamber, where an inlet to the reaction chamber is configured to be coupled to an oxygen source that contains molecular oxygen. An optical excitation source is optically coupled to the reaction chamber and is configured to generate radiation in an ultraviolet wavelength range. The radiation is configured to excite a proportion of the molecular oxygen in the reaction chamber, without the use of a plasma generator, to form atomic oxygen such that the atomic oxygen is able to react with the molecular oxygen in the reaction chamber to form ozone. An outlet from the reaction chamber is configured to emit a gas mixture comprising the atomic oxygen, the molecular oxygen, and the ozone.

In some aspects, a method for generating an active oxygen species includes introducing molecular oxygen into an inlet of a reaction chamber and generating radiation from an optical excitation source in the reaction chamber to excite a proportion of the molecular oxygen to form atomic oxygen. The radiation is in an ultraviolet wavelength range. The method also includes forming ozone, without the use of a plasma generator, by reacting the atomic oxygen with the molecular oxygen that is present in the reaction chamber, and emitting, from an outlet of the reaction chamber, a gas mixture comprising the atomic oxygen, the molecular oxygen and the ozone.

In some aspects, a system for deposition of an oxide film includes a material deposition system and a photoreactor. The photoreactor includes a reaction chamber and an inlet to the reaction chamber, the inlet configured to be coupled to an oxygen source that contains molecular oxygen. An optical excitation source is optically coupled to the reaction chamber, where the optical excitation source is configured to generate radiation in an ultraviolet wavelength range. The radiation is configured to excite a proportion of the molecular oxygen in the reaction chamber, without the use of a plasma generator, to form atomic oxygen such that the atomic oxygen is able to react with the molecular oxygen in the reaction chamber to form ozone. An outlet from the reaction chamber is coupled to the material deposition system to deliver a gas mixture comprising the atomic oxygen, the molecular oxygen, and the ozone.

### BRIEF DESCRIPTION OF DRAWINGS

Embodiments of the present disclosure will be discussed with reference to the accompanying drawings.

FIG. 1 is an overview diagram of a system for generating active oxygen species, in accordance with some embodiments.

FIG. 2 is a figurative overview diagram of a photoreactor of the system illustrated in FIG. 1, in accordance with some embodiments.

FIGS. 3A-3B are graphs of molecular oxygen and ozone absorption spectra extending over the vacuum ultraviolet (VUV) to ultraviolet (UV) wavelength ranges.

FIG. 4 is a plot showing the absorption selectivity of molecular oxygen versus ozone for three selected excimer wavelengths.

FIG. 5 is a graph of the effective path length of molecular oxygen as a function of reaction chamber pressure for the selected excimer wavelengths shown in FIG. 4, in accordance with some embodiments.

FIG. 6 is a flowchart of a method for generating active oxygen species, in accordance with some embodiments.

FIG. 7 is a reaction pathway diagram showing the formation of atomic oxygen from molecular oxygen, the combination of molecular oxygen with atomic oxygen to form ozone, and the dissociation of ozone to molecular oxygen, in accordance with some embodiments.

FIG. 8A is a graph of the evolution of concentrations of molecular oxygen, atomic oxygen and ozone in a reaction chamber having a 172 nm excitation source in accordance with the reaction pathway diagram illustrated in FIG. 7.

FIG. 8B is a graph showing the general dependence of ozone and atomic oxygen concentration on the power of the optical excitation source, in accordance with some embodiments.

FIGS. 9A-9C show various views of nozzle designs for use with photoreactors of the present disclosure, in accordance with some embodiments.

FIGS. 9D-9E show side views of example angular distributions of emitted gas mixtures from beam forming nozzles, in accordance with some embodiments.

FIG. 10A is a graph of the ozone absorption spectrum in the ultraviolet-C (UVC) wavelength range showing the absorption peak at approximately 250 nm for use as a probe wavelength, in accordance with some embodiments.

FIG. 10B is a graph of a deuterium emission spectrum, in accordance with some embodiments.

FIG. 10C is a graph of transmission as a function of photoreactor absorption wavelength, in accordance with some embodiments.

FIGS. 10D-10E are overview diagrams of a concentration monitoring system to measure the concentration of generated ozone and/or atomic oxygen in the reaction chamber of a photoreactor, in accordance with some embodiments.

FIGS. 11A-11B show isometric and bottom views, respectively, of a photoreactor, in accordance with some embodiments.

FIGS. 12A-12B show front and back perspective views, respectively, of an excitation source, in accordance with some embodiments.

FIGS. 13A-13E show various views of a photoreactor, in accordance with some embodiments.

FIGS. 14A-14B show two side views of a photoreactor with a concentrator monitor, in accordance with some embodiments.

FIG. 15 is a figurative diagram of a deposition arrangement incorporating an active oxygen species generating system, in accordance with some embodiments.

In the following description, like reference characters designate like or corresponding parts throughout the figures.

### DETAILED DESCRIPTION

The present disclosure relates to generating active oxygen species for processes, such as those requiring ozone species. Active oxygen species produced by the present systems and methods include ozone and atomic oxygen. Processes that can use the systems and methods described herein include material deposition processes, such as for forming (manufacturing) layers of semiconducting materials. In some aspects, the present disclosure relates to generating active oxygen species for the deposition of oxide related layers in a deposition process.

Although techniques exist for producing active oxygen species as described above, these techniques have disadvantages. For example, conventional processes using DBD ozone generators produce ozone in the form of liquid ozone. As would be appreciated, liquid ozone is highly reactive and requires onerous hazard management procedures to ensure its safe use because any formation of oxygen, which is an exothermic process, could cause an explosion. Furthermore, any valving will react with ozone and oxidize to form oxygen which again is dangerous. Additionally, the capital equipment costs associated with generating ozone by the combined DBD and cryogenic distillation process are significant. In another example, the technique of using an RF microwave field in a vacuum chamber to form a plasma and generate atomic oxygen also has disadvantages. Although this plasma-based active oxygen specie generation process is able to provide a “point of use” supply of atomic oxygen without the requirement for cryogenic storage (unlike the ozone generation process referred to above), these plasma-based processes typically have a very low efficiency with only 1% to 5% of atomic oxygen being produced in the atomic oxygen/molecular oxygen output. As would be appreciated, the presence of significant concentrations of molecular oxygen will not only compromise the deposition process but can also cause oxidation of heating elements involved in the deposition process.

The present disclosure provides various methods, apparatuses and systems for continuous and on-demand generation of active oxygen species. Contrary to conventional arrangements, active oxygen generation methods and systems in accordance with the present disclosure may be configured to generate a continuous beam containing active oxygen species without the requirement of hazardous storage arrangements. A continuous beam containing the ozone (or active oxygen species) may be generated for on the order of minutes or hours, depending on the needs of the deposition process for which the ozone is being supplied. For example, a continuous beam containing ozone (or active oxygen species) may be generated for at least 1 minute, at least 10 minutes, at least 1 hour, up to 10 hours, or longer than 10 hours, or from 1 minute to 100 hours. In some examples, the ozone (or other active oxygen species) concentration in the generated gas mixture is at least 5%, at least 6%, at least 7%, or at least 10%, and in other examples may be greater than 30% or greater than 40%.

Aspects of the present disclosure uniquely recognize that there is a reaction chamber size and pressure range that is advantageous to both i) the production of highly reactive atomic oxygen from molecular oxygen by photodissociation and further ii) the formation of ozone in the reaction chamber as opposed to competing reactions which operate to decrease the ozone concentration. The trade-offs required to balance various factors to successfully form ozone at proper levels for material deposition are complex and not straightforward to achieve. These trade-offs are addressed in the present disclosure with unique insights into the interactions between these factors and by utilizing specialized design features in the systems and methods for producing ozone. Embodiments enable active oxygen species to be reliably produced and supplied on-demand, such as in a continuous stream.

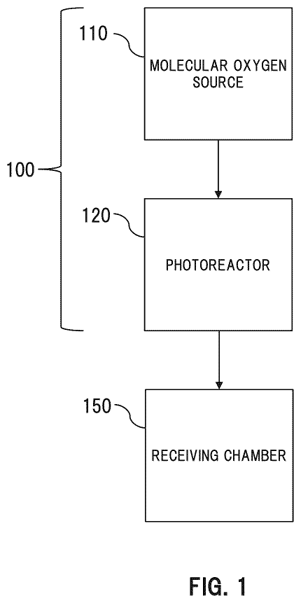

FIG. 1 is a block diagram of a system 100 for generating active oxygen species according to an embodiment. System 100 in this example comprises a molecular oxygen source 110 and a photoreactor 120 (i.e., a photoreaction chamber) configured to emit active oxygen species, such as in the form of a beam and in some cases a continuous beam, from the photoreactor 120. The system 100 may be coupled to a receiving chamber 150 that will utilize the active oxygen species generated by the photoreactor 120. In some examples, the receiving chamber 150 may be a chamber of a material deposition system, such as molecular beam epitaxy system.

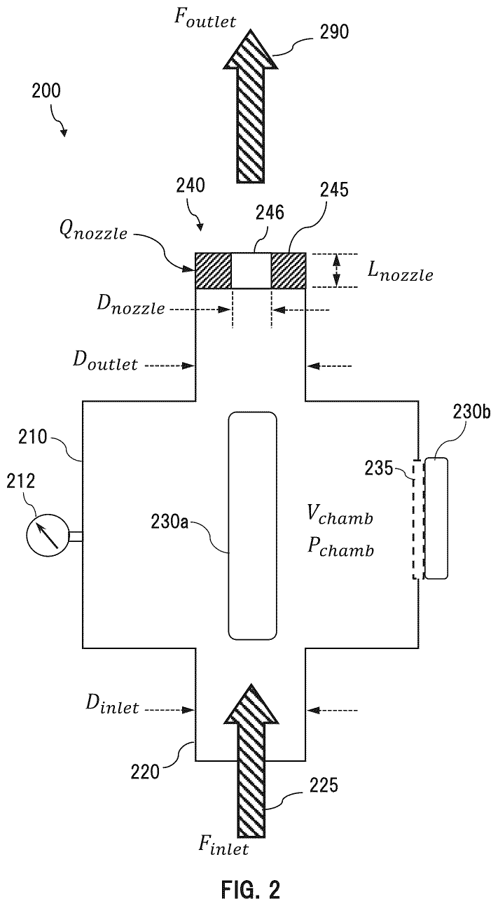

FIG. 2 shows a cross-sectional schematic of a photoreactor 200 corresponding in one example to photoreactor 120 of the active oxygen species generation system illustrated in FIG. 1. In this example, photoreactor 200 comprises a reaction chamber 210, an inlet 220 to the reaction chamber 210, and an outlet 240 from the reaction chamber 210. The reaction chamber 210 has a volume V_{chamb} and operates with a pressure P_{chamb}. A pressure sensor 212 is coupled to the reaction chamber 210 to monitor the pressure P_{chamb} inside the reaction chamber 210 (i.e., the working pressure, operating pressure, chamber pressure) before, during, and/or after generating an active oxygen species as shall be described throughout this disclosure. The inlet 220 (with diameter Dᵢₙₗₑₜ) is configured to be coupled to a source that contains molecular oxygen (e.g., molecular oxygen source 110 of FIG. 1), for introducing the molecular oxygen as an input gas 225 with flow rate Fᵢₙₗₑₜ into the reaction chamber 210. Outlet 240 with diameter Dₒᵤₗₑₜ is configured to emit a beam 290 of active oxygen species in the form of a gas mixture (with flow rate Fₒᵤₗₑₜ) comprising the atomic oxygen, the molecular oxygen, and the ozone.

An optical excitation source 230a or 230b is optically coupled to the reaction chamber 210 such that the optical excitation source 230a-b transmits light radiation but no physical particles into the reaction chamber 210. In some examples, the photoreactor 200 may utilize the optical excitation source 230a that is located inside reaction chamber 210. In one example, the optical excitation source 230a may be located centrally in the reaction chamber 210 and may be cylindrical in shape, emitting radiation into the chamber. In other examples, the photoreactor 200 may utilize the optical excitation source 230b that is located outside the reaction chamber. Optical excitation source 230b is optically coupled to the interior of the reaction chamber through a window 235 that is optically transparent to light (i.e., radiation) emitted by the optical excitation source 230b. In one example as shown, optical excitation source 230b may be a flat light source (rather than a cylindrical source) that optically transmits radiation through window 235 to the interior of reaction chamber 210.

Optical excitation source 230a-b is configured to generate radiation in an ultraviolet wavelength range. The wavelength range generated by optical excitation source 230a-b may include an ultraviolet (UV) wavelength range of 110 nm to 400 nm, such as in a vacuum ultraviolet (VUV) wavelength range of 125 nm to 180 nm. Optical excitation source 230a-b functions to optically excite a proportion of the introduced molecular oxygen (from input gas 225) in the reaction chamber to form atomic oxygen by photodissociation. The atomic oxygen then reacts with the molecular oxygen present in the reaction chamber 210 to form ozone. Consequently, a gas mixture is formed in the reaction chamber 210 comprising atomic oxygen, molecular oxygen, and ozone. The gas mixture is emitted from outlet 240 as the beam 290 of active oxygen species with flow rate Fₒᵤₜₗₑₜ having a beam profile as will be described herein.

Photoreactor 200 also includes a beam forming nozzle 245 within outlet 240, in which the nozzle 245 has an aperture 246 that allows gas flow to pass through. Beam profile forming characteristics of beam forming nozzle 245 primarily depend on a characteristic length of the nozzle in the direction of emission, L_{nozzle}, and on the conductance of the nozzle, Q_{nozzle}, which is primarily dependent on a characteristic diameter of the nozzle aperture, D_{nozzle}. In this manner, the beam profile and outlet working pressure of the photoreactor 200 may be configured in accordance with requirements of the deposition process to which the beam 290 of active oxygen species is being delivered.

Explanation of how the photoreactor 200 is uniquely designed to generate the gas mixture comprising active oxygen species shall now be described. Technical insight into what factors affect the reactions between molecular oxygen, atomic oxygen, and ozone, and how to address the complex interactions between those factors, required novel approaches that were not straightforward from conventional practices.

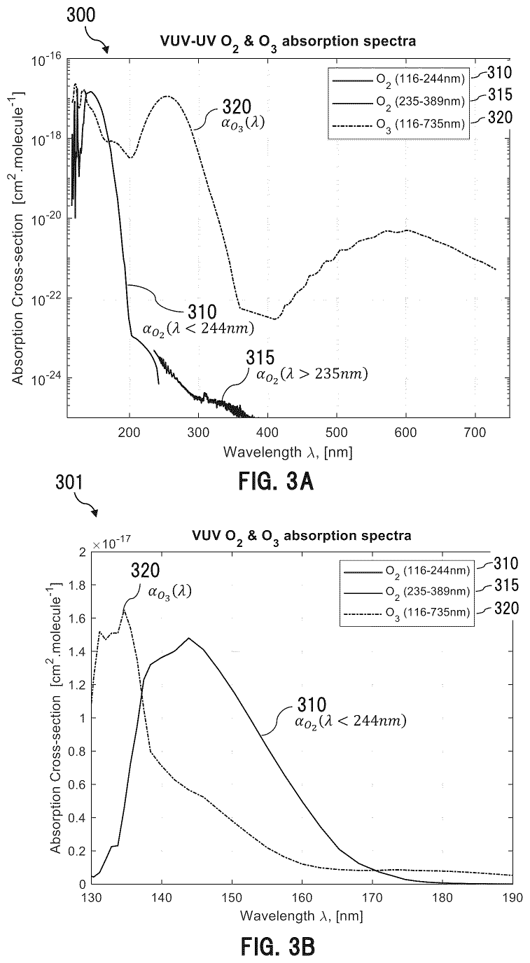

Referring to FIG. 3A, there is shown a graph 300 of experimental results for absorption spectra for molecular oxygen and ozone. The absorption cross-section a (ability or measure of a probability of a molecule to absorb photons, with units of cm²/molecule) is on the Y-axis, plotted as a function of wavelength λ (nanometers) on the X-axis. The spectra extend over the vacuum ultraviolet to ultraviolet wavelength ranges, as well as beyond those ranges to approximately 700 nm. Graph 301 of FIG. 3B shows experimental results that are similar to those in FIG. 3A except that graph 301 focuses on the VUV wavelength range, showing spectra in the wavelength range of 130 nm to 190 nm.

In FIG. 3A, two absorption spectra are shown for molecular oxygen, the first ranging from 116 nm to 244 nm as shown by curve 310, and the second ranging from 235 nm to 389 nm as shown by curve 315. Curves 310 and 315 correspond to two different data sets. Curve 320 is the absorption spectrum for ozone. As can be seen from FIGS. 3A and 3B, in the wavelength range of 136 nm to 172 nm the absorption spectrum for molecular oxygen (curve 310) is approximately equal to or exceeds the absorption spectrum of ozone (curve 320).

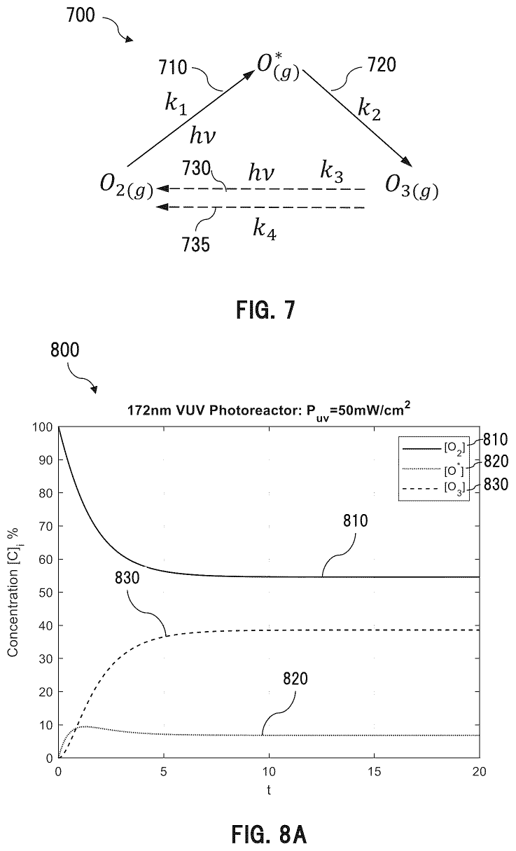

Examples of the present disclosure utilize this insight that molecular oxygen has higher radiation absorption than ozone at certain VUV wavelengths. In some examples, optical excitation source 230a-b of photoreactor 200 produces radiation in the VUV wavelength range, such as producing radiation in the 125 nm to 180 nm wavelength band. In this manner, molecular oxygen undergoes excitation to produce atomic oxygen by photodissociation. Through careful design of the photoreactor and balancing of reaction conditions using technical insights described herein, the photodissociation of molecular oxygen is balanced with competing reactions (see FIG. 7) to produce ozone.

In some examples, optical excitation source 230a-b may comprise one or more light emitting diodes, a laser source, or a gas-discharge source. In some examples, optical excitation source 230a-b is an excimer lamp. Various excimer lamps have different emission wavelengths depending on the working excimer molecule as shown in Table 1 below. As can be seen in Table 1, these wavelengths are in the VUV range and may be used in the present photoreactor systems, when designed carefully with other reaction factors as described herein.

TABLE 1

| Excimer | Wavelength | Photon Energy |
|---|---|---|
| Molecule | (nm) | (eV) |
| Ar₂* | 126 | 9.84 |
| Kr₂* | 146 | 8.49 |
| F₂* | 158 | 7.85 |
| ArBr* | 165 | 7.52 |
| Xe₂* | 172 | 7.21 |
| ArCl* | 175 | 7.08 |
| KrI* | 190 | 6.49 |
| ArF* | 193 | 6.42 |

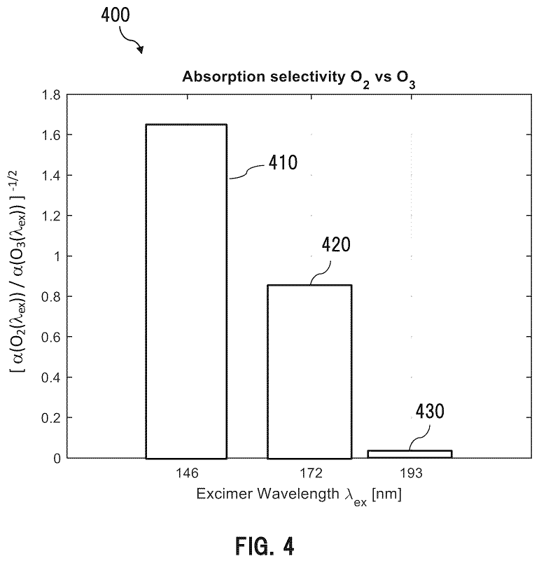

Referring to FIG. 4, chart 400 depicts calculated absorption selectivity of molecular oxygen versus ozone for three selected excimer wavelengths, where the chart 400 was derived from the data of FIGS. 3A-3B. The Y-axis value is the inverse square root of the ratio of the absorption selectivity of molecular oxygen (“α(O₂(λₑₓ))”) at a particular excimer wavelength to the absorption selectivity of ozone (“α(O₃(λₑₓ))”) at the excimer wavelength. Bar 410 represents the results for 146 nm (Kr₂*), bar 420 represents 172 nm (Xe₂*), and bar 430 represents 193 nm (ArF*). As can be seen, for increasing wavelength the absorption selectivity of molecular oxygen relative to ozone decreases.

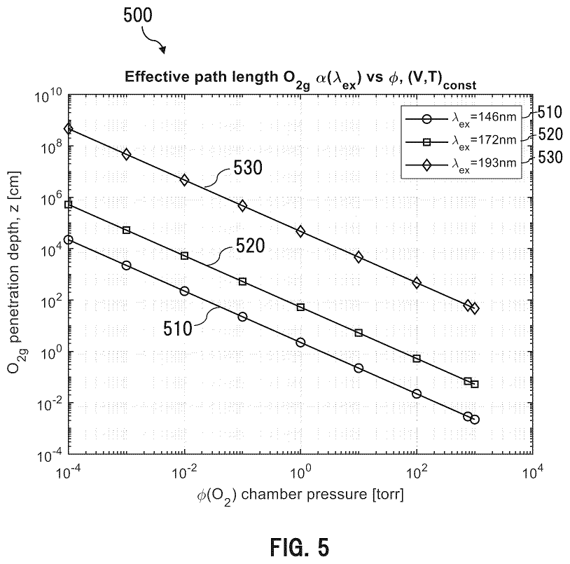

FIG. 5 shows a graph 500 modelled according to this disclosure, of the effective path length of molecular oxygen before photodissociation. The molecular oxygen penetration depth (centimeters) on the Y-axis is plotted as a function of the pressure of molecular oxygen (Torr) in the reaction chamber on the X-axis for the selected excimer wavelengths shown in FIG. 4. Graph 500 assumes a reaction chamber having a cylindrical configuration and a constant volume V of approximately 0.02 m³ and operating at ambient temperature T. Line 510 is the penetration depth as a function of pressure when exposed to 146 nm, line 520 is for 172 nm, and line 530 is for 193 nm. As can be seen from graph 500, the expected penetration depth for an oxygen molecule before it is excited and photodissociated to form atomic oxygen will decrease as the reaction chamber pressure increases. Also, the expected penetration depth is dependent on the wavelength of the excimer wavelength, where the depth decreases for shorter excitation wavelengths within this range. This is consistent with FIG. 3B, given that for this wavelength range (146-193 nm) the absorption cross section increases with decreasing wavelength.

Using the graph 500, a working pressure for a reaction chamber having a characteristic dimension (e.g., diameter, width and/or length on the order of 0.1 m to 1 m) may be determined for a selected wavelength. In an example, the pressure in the photoreactor may be between 10⁻⁴ Torr to 10² Torr (on the order of 10⁻² Pascals to 10⁴ Pascal) depending on the configuration of photoreactor. The pressure, chamber size, and excitation wavelengths are selected to be sufficient to ensure that molecular oxygen is photodissociated to form atomic oxygen in the reaction chamber within a certain timescale, for example on the order of at least seconds or, tens of seconds. These system features are further chosen to select preferentially for the formation of ozone through the combination of molecular oxygen and atomic oxygen as opposed to the competing reaction of ozone reacting with atomic oxygen to form molecular oxygen (e.g., see FIG. 7). The long timescale for the reaction means that the residence time of the molecular oxygen in the reaction chamber will be high enough to enable the molecular oxygen to absorb light and create ozone. The residence time is based on balancing various design factors including chamber pressure, chamber volume, wavelength of the optical excitation source, and molecular oxygen flow rate. Achieving the proper conditions for the reaction chains to occur can successfully result in ozone concentrations in the produced gas mixture of at least 5%, or at least 6%, or at least 7%, or at least 10%, or 10-15%, or at least 30%. In some cases, the chamber size is selected based on the penetration depth to ensure that a large fraction of molecular oxygen is photodissociated. The fraction of molecular oxygen that is photodissociated, then affects the rates of the ozone generation compared to the competing reactions, which thereby can affect the timescale of the reaction and/or the residence times of the ozone and other active oxygen species within the chamber.

In some examples, a xenon excimer lamp having an excitation wavelength of 172 nm is employed as the optical excitation source for the photoreactor. Xenon excimer lamps have a benefit of being commercially available and further having relatively good absorption selectivity for ozone as can be seen in FIG. 4. In some examples, the optical excitation source may be configured to operate over an extended wavelength range. In such cases, operation of the photoreactor may be adjusted accordingly for wavelengths greater than 180 nm where the absorption selectivity for oxygen versus ozone significantly reduces (see FIG. 3B and FIG. 4).

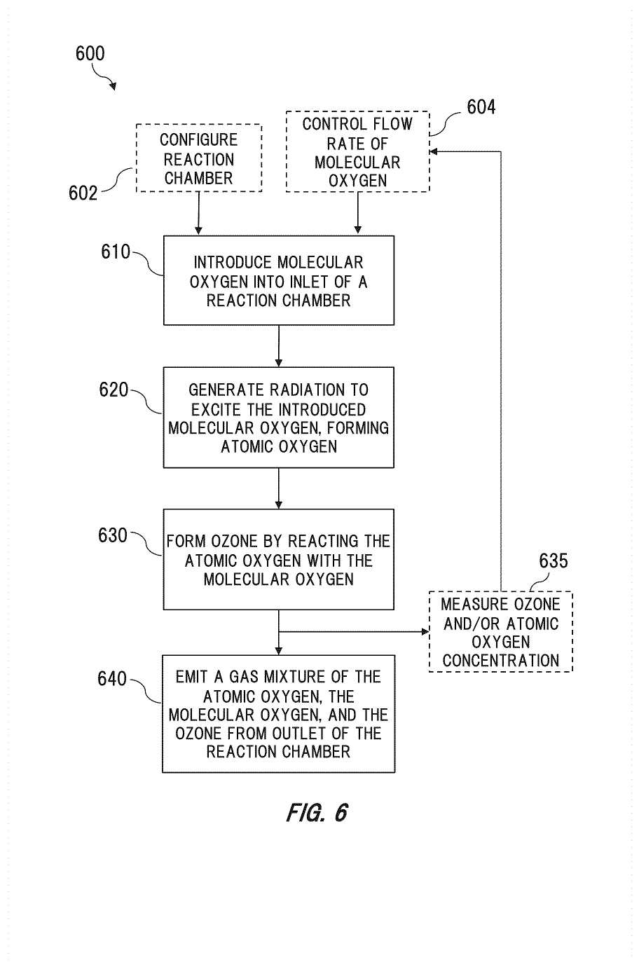

FIG. 6 shows a flowchart of a method 600 for generating active oxygen species in accordance with embodiments, such as a beam containing active oxygen species. The method may be utilized for fabricating semiconducting materials, such as oxide films. In some examples, the method 600 may employ active oxygen species generation system 100 illustrated in FIG. 1 and photoreactor 200 illustrated in FIG. 2, or other embodiments of systems disclosed herein. In some examples, the pressure in the reaction chamber 210 may be higher than in the receiving chamber of the deposition process (e.g., receiving chamber 150 of FIG. 1), where the pressure in the receiving chamber may be a vacuum environment. That is, the receiving chamber may be a vacuum chamber. In some examples, the beam containing active oxygen species is supplied to a deposition process such as molecular beam epitaxy which may require an emission pressure between 10⁻⁵ Torr to 10−8 Torr (on the order of 10⁻³ Pascals to 10⁻⁶ Pascals) at the outlet depending on deposition conditions.

At block 610, molecular oxygen is introduced into inlet 220 of reaction chamber 210. At block 620, radiation is generated from optical excitation source 230a (inside the reaction chamber) or optical excitation source 230b (outside the reaction chamber) to excite a proportion of the molecular oxygen in the reaction chamber. In some aspects, the ultraviolet wavelength range of the radiation generated by the optical excitation source wavelength is 125 nm to 180 nm, such as 172 nm in one example, or 146 nm or 193 nm in other examples. The excited molecular oxygen forms atomic oxygen which will in turn, in block 630, react with molecular oxygen present in the reaction chamber to form ozone. Thus, blocks 620 and 630 involve generating radiation from an optical excitation source inside or coupled to the reaction chamber to excite a proportion of the molecular oxygen to form atomic oxygen, wherein the radiation is in an ultraviolet wavelength range; and forming ozone by reacting the atomic oxygen with the molecular oxygen that is present in the reaction chamber. The ozone is formed without the need for a plasma source as in conventional techniques. In some examples, the method 600 involves sustaining a pressure less than 100 Torr (13332 Pascals) in the reaction chamber during the forming of the ozone.

Block 640 involves emitting, from outlet 240 of the reaction chamber, a gas mixture comprising the atomic oxygen, the molecular oxygen and the ozone. In some aspects, in the emitting of block 640, the gas mixture is emitted as a beam containing the active oxygen species (comprising at least one of the atomic oxygen or the ozone) from the reaction chamber, such as being emitted continuously. In some aspects, the emitting the gas mixture comprises using a nozzle (e.g., nozzle 245) coupled to the outlet 240 to deliver the gas mixture as a beam containing the active oxygen species to a receiving chamber (e.g., receiving chamber 150), wherein the nozzle is configured to produce a desired beam distribution and a desired pressure differential between the reaction chamber and the receiving chamber.

Although blocks 610 to 640 are shown sequentially in FIG. 6, the blocks may occur simultaneously and repeatedly as the molecular oxygen is continued to be supplied to the reaction chamber to continuously produce the gas mixture.

In various embodiments, the pressure in the reaction chamber may be monitored using a pressure sensor to determine when the predetermined pressure value is reached and/or to maintain the predetermined pressure.

In some cases, in the introducing of block 610, the molecular oxygen is introduced continuously into the reaction chamber to in turn form a continuous beam containing active oxygen species. In these cases, the flow rate of introduced molecular oxygen at the inlet to reaction chamber, Fᵢₙₗₑₜ, will be approximately equivalent to the flow rate of the beam, Fₒᵤₜₗₑₜ, emitted from the outlet 240 of reaction chamber 210, where the emitted beam contains active oxygen species. The method 600 operates to continuously generate the active oxygen species, e.g., as a beam containing the active oxygen species. Accordingly, the continuous photoreaction process may be characterised by a characteristic flow rate. In some examples, in the introducing of the molecular oxygen in block 610, the molecular oxygen has a flow rate less than or equal to 100 SCCM (standard cubic centimeters per minute). In examples, the characteristic flow rate of the process may be between 0.1 SCCM to 100 SCCM, or between 1 SCCM to 10 SCCM, or between 1 SCCM to 5 SCCM. As would be appreciated, a beam containing an active oxygen species emitted at a relatively low flow rate, but with a high ozone concentration, can be advantageous to the deposition process.

In other cases, in the introducing of block 610, the molecular oxygen is introduced until the reaction chamber is pressurized to a predetermined pressure. In these cases, block 610 may involve initially charging the reaction chamber 210 to a target pressure rather than inputting a continuous flow of molecular oxygen. In such an operating mode, block 610 involves an initial input of the molecular oxygen to form a pressurized chamber (e.g., at approximately 100 Torr as the predetermined/target pressure value). This amount or quantity of molecular oxygen in the reaction chamber is then used to generate ozone for a predetermined time. The volume of the reaction chamber will determine the amount of ozone that is generated from the pressurized chamber. The pressure may be replenished with subsequent charges of molecular oxygen as needed to reach the desired pressure. In this manner, the gas mixture can still be continuously produced by introducing molecular oxygen in a stepwise fashion (e.g., periodic inputs of the molecular oxygen).

In some examples, the method 600 may optionally include block 602 of configuring the reaction chamber, such as by choosing a shape, dimensions, and/or volume of the reaction chamber. The configuring of block 602 is performed to provide a residence time for the molecular oxygen that is sufficient to form ozone (or that preferentially produces ozone), where the configuring is based on factors including an operating pressure, a wavelength of the radiation, and a flow rate of the molecular oxygen introduced into the inlet of the reaction chamber. Block 602 may involve configuring a reaction chamber and other system parameters to favorably select a formation reaction pathway of molecular oxygen with atomic oxygen to form ozone rather than a loss reaction pathway where the ozone forms the molecular oxygen (e.g., see FIG. 7 and related descriptions throughout this disclosure). The volume of the reaction chamber and a conductance of the exit aperture of the nozzle, along with other parameters, such as one or more of an operating pressure, a wavelength of the radiation, a power intensity of the radiation, and/or a flow rate of the molecular oxygen into the inlet of the reaction chamber can be adjusted to favorably select the formation reaction pathway.

In some cases, a volume of the chamber, along with other parameters such as flow rate, and a conductance of the exit aperture can be adjusted to provide desired residence times for the atomic oxygen, the molecular oxygen, and the ozone. The residence times are related to which reactions occur, and if it is favorable for a formation reaction pathway of molecular oxygen with atomic oxygen to form ozone rather than a loss reaction pathway where the ozone forms the molecular oxygen. The volume of the chamber will affect the photon flux, where the likelihood of a photon impacting an oxygen molecule will increase as the chamber size is decreased. Block 602 may involve configuring a volume of the reaction chamber, such as setting or calculating a desired volume of the chamber, to provide residence times for the atomic oxygen, the molecular oxygen, and the ozone to favorably select a formation reaction pathway of molecular oxygen with atomic oxygen to form ozone rather than a loss reaction pathway where the ozone forms the molecular oxygen, wherein the volume is based on one or more of an operating pressure, a wavelength of the radiation, a power intensity of the radiation, and/or a flow rate of the molecular oxygen introduced into the inlet of the reaction chamber. In some embodiments, one or more of an operating pressure, a wavelength of the radiation, a power of the radiation, and a flow rate of the molecular oxygen into the inlet of the reaction chamber are configured for a given volume of the reaction chamber to provide residence times for the atomic oxygen, the molecular oxygen, and the ozone to favorably select a formation reaction pathway of molecular oxygen with atomic oxygen to form ozone rather than a loss reaction pathway where the formed ozone forms molecular oxygen.

In any of these scenarios, the operating pressure may be a range of operating pressures to be used; the radiation wavelength may be a range of wavelengths (e.g., target wavelength with an operating tolerance of the optical excitation source); and the flow rate of the molecular oxygen may be a range of flow rates to be used during operation. In any of the embodiments, an operating temperature or temperature range may also be configured to create the favorable conditions. Considerations in producing these favorable conditions, using insights explained herein, are described in relation to FIG. 7 and elsewhere in this disclosure.

In some examples, block 602 may also include optimizing the operating pressure for the volume of the reaction chamber. Increasing the pressure will increase the number of molecules per volume, consequently increasing the likelihood of photons interacting with oxygen molecules. The pressure level should also take into consideration the excitation wavelength as described for FIG. 5 to desirably cause gas molecules to have a residence time in the reaction chamber of at least several seconds, such as at least tens of seconds, to favorably select the reaction of molecular oxygen with atomic oxygen to form ozone rather than the competing reaction of ozone reacting with atomic oxygen to form molecular oxygen. In another design consideration, the flow rate of the input molecular oxygen and of the produced gas mixture will depend on the desired pressure difference between the reaction chamber and the system that is receiving the gas mixture. All these factors for configuring the reaction chamber and its operating conditions must be taken into account, with trade-offs made to achieve the needed photon flux (photons per area per second) at a certain pressure and volume and to enable a sufficient residence time of O₂ molecules in the reaction chamber for photodissociation to take place. Further details of the molecular oxygen, atomic oxygen, and ozone reactions are described in FIG. 7.

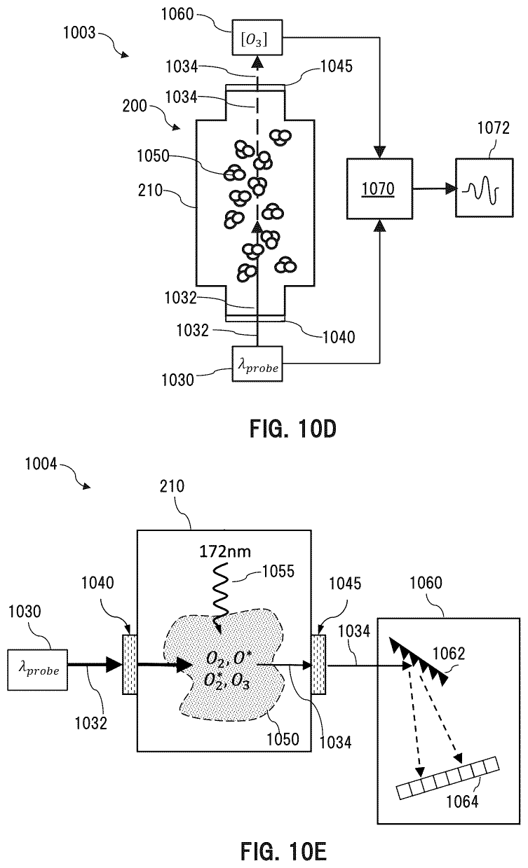

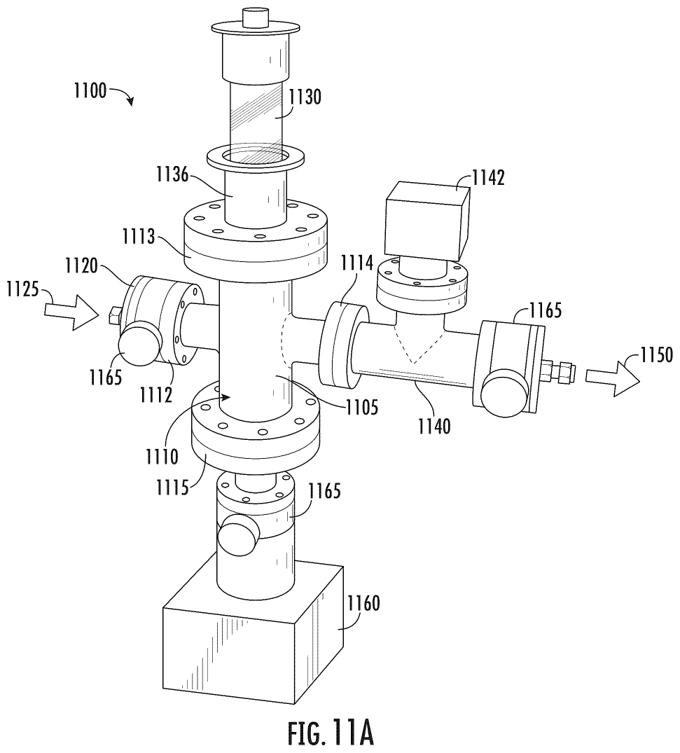

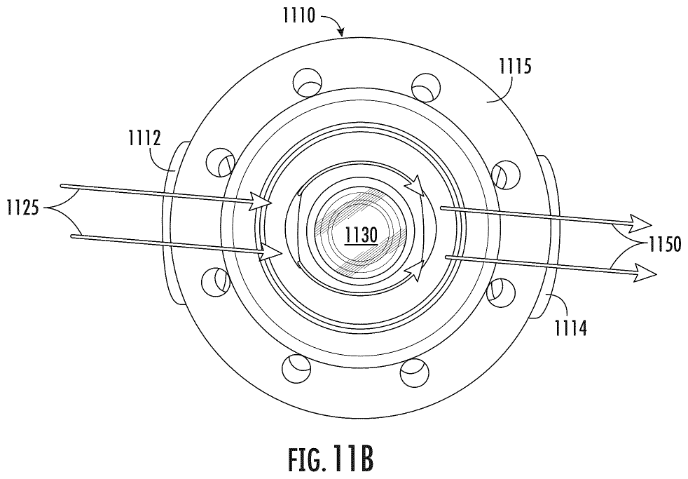

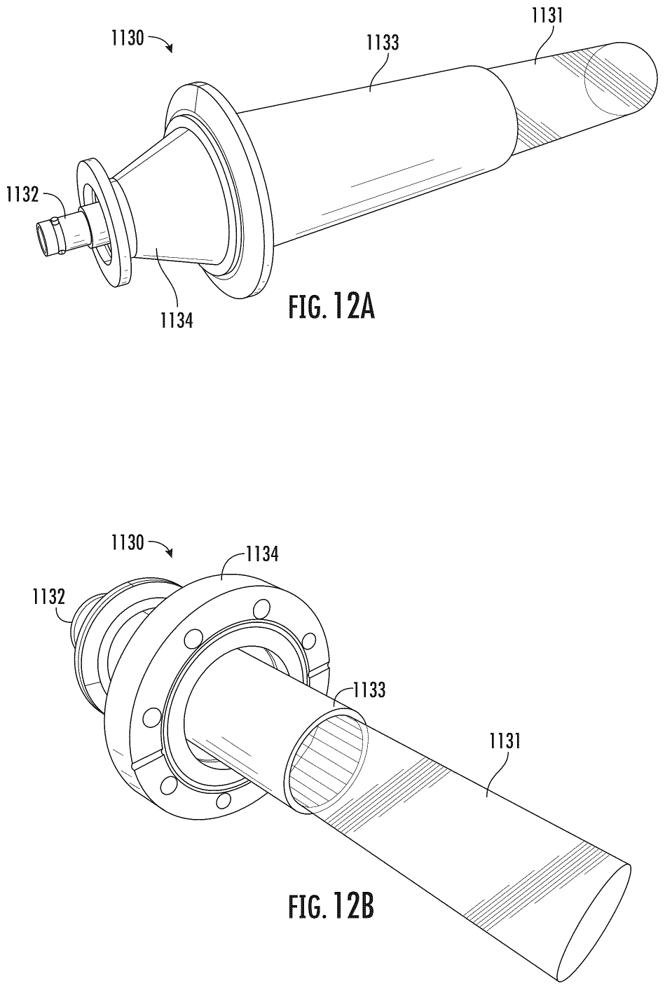

Still referring to FIG. 6, the method 600 may optionally include block 604 of controlling a flow rate of the molecular oxygen introduced into the reaction chamber, where the controlling may be based on an ozone concentration in the reaction chamber measured by an ozone concentration monitor and/or an atomic oxygen concentration measured by an atomic oxygen concentration monitor (e.g., as described in FIGS. 10A-10E). In such cases, the method 600 may also include measuring the ozone and/or atomic oxygen concentration in block 635. The measuring of block 635 may include emitting, from an emission source, a probe beam through a first window in a wall of the reaction chamber, the probe beam having a probe wavelength that is more strongly absorbed by the ozone (or atomic oxygen) than by the molecular oxygen (e.g., see FIG. 10A); and receiving, by a detector, the probe beam after passing through a second window in the wall of the reaction chamber. Measurements from block 635 may be used as feedback for block 604 to adjust the flow rate of molecular oxygen if the ozone concentration is too low or too high. Block 604 may also include controlling a pressure in the reaction chamber using feedback from a pressure sensor that is connected to a pump, wherein the pump is coupled to the reaction chamber. The controlling of the flow rate, power intensity of the optical excitation source, pressure, or other parameters may be performed using a controller comprising a processor, that uses feedback (e.g., measurements of pressure, ozone concentration, temperature) to make adjustments for maintaining desired conditions.

Details of the reactions for forming ozone shall now be described.

In one example, and without being bound by any particular theory, a reaction rate approach may be applied to characterize the performance of a system for generating an active oxygen species in accordance with examples of the present disclosure. In accordance with this approach, a process comprising reactants A and B forming products P and Q with stoichiometric coefficients (a, b, p, q), respectively, may be represented as follows:

$$a A + b B \to p P + q Q \qquad ( Equation 1 )$$

with the change of concentration of [X], X selected from any one of A, B, P or Q, being defined as:

$$\frac{d [ X ]}{dt} = \pm {{k}_{i} [ X ]}^{m} \qquad ( Equation 2 )$$

In the above equation, kᵢ is the rate constant, m is the reaction order, and the sign “±” (plus or minus) represents an increasing/decreasing concentration respectively.

In this approach, the coupled processes of oxygen photodissociation into reactive and short-lived atomic oxygen and the subsequent attachment process to form ozone may be understood in terms of the bimolecular reaction pathways shown in FIG. 7, which shows a reaction pathway diagram 700 depicting the three main reaction pathways 710, 720 and 730 relevant to forming ozone. Reaction pathway 710, reaction pathway 720, and reaction pathway 710 with 720 are formation reaction pathways, while a loss reaction pathway comprises one or both of reaction pathways 730 and 735 that form molecular oxygen.

The first reaction pathway 710 is the forming of atomic oxygen (O_{(g)}*) from molecular oxygen (O_{2(g)}) by photodissociation (photon hv):

$${O}_{2} + h ν \to {O}^{*} + {O}^{*} \qquad ( Equation 3 )$$

In this example, this first reaction pathway 710 is characterized by reaction rate k₁ having a dimension of [s⁻¹] (i.e., rate per second). Promoting this first reaction pathway 710 for forming atomic oxygen from molecular oxygen is a goal of the active oxygen system. First reaction pathway 710 can be favored (i.e., increased in likelihood or occurrence; have a higher probability of occurring and/or a faster rate of one reaction over another) by adjusting the reaction chamber pressure. Higher pressure increases the likelihood of interactions to occur, since the mean free path of a gas particle is inversely proportional to pressure. Higher pressure also increases the likelihood of interactions to occur between the excitation photons and the species in the chamber, for example, when a photon interacts with molecular oxygen to form atomic oxygen in first reaction pathway 710. First reaction pathway 710 can also be favored by adjusting the radiation power of the optical excitation source, where higher radiation levels (power of the radiation) provide more photons to cause photodissociation.

The second reaction pathway 720 is another formation reaction pathway involving the attachment reaction of molecular oxygen with atomic oxygen to form ozone O_{3(g(}):

$${O}_{2} + {O}^{*} \to {O}_{3} \qquad ( Equation 4 )$$

This second reaction pathway 720 (which may also be referred to as an attachment reaction pathway) is characterized by reaction rate k₂ having a dimension of [cm⁶molecule⁻²s⁻¹]. The second reaction pathway 720 for producing ozone is also desirable for the active oxygen systems of the present disclosure and can be favored by adjusting the reaction chamber pressure (higher pressure increases the likelihood of interactions to occur). When comparing reaction pathways 710 and 720, higher pressure will favor ozone via second reaction pathway 720 whereas lower pressure will favor producing atomic oxygen via first reaction pathway 710 because first reaction pathway 710 also utilizes photodissociation.

The bottom of the reaction pathway diagram 700 is the competing loss reaction pathway for ozone which has two component reaction pathways 730 and 735. The first, and most significant, component loss reaction pathway 730 is the photodissociation of ozone to form molecular oxygen and atomic oxygen:

$${O}_{3} + h ν \to {O}_{2} + {O}^{*} \qquad ( Equation 5 )$$

This first loss reaction component pathway 730 is characterized by reaction rate k₃ having dimensions of [s⁻¹]. Increasing the power from the optical excitation source will increase the likelihood that the ozone will form molecular oxygen and atomic oxygen by photodissociation. However, as described above, desirable formation reaction pathway 710 can also be favored by increasing the power of the optical excitation source. Therefore, in some cases, the power from the optical excitation source is balanced with other parameters (e.g., flow rate and exit aperture conductance) to increase the ratio of total active oxygen to molecular oxygen. In some cases, the power from the optical excitation source and other parameters (e.g., flow rate and exit aperture conductance) are set to increase the ratio of active atomic oxygen to ozone.

The second loss reaction component pathway 735 relates to the reaction of ozone and atomic oxygen (i.e., ozone decaying) as follows:

$${O}_{3} + {O}^{*} \to 2 {O}_{2} \qquad ( Equation 6 )$$

which is characterized by reaction rate k₄ having dimensions [cm⁶molecule⁻²s⁻¹]. The loss reaction pathway 730 (Equation 5) is less detrimental to the production of active oxygen species in the present systems and methods because loss reaction pathway 730 (Equation 5) produces atomic oxygen (O*) along with the molecular oxygen. That is, loss reaction pathway 730 will decrease the ratio of total active oxygen compared to O₂ (i.e., [O₃+O*]/[O₂]) but increase the ratio [O*]/[O₃]. In comparison, loss reaction pathway 735 (Equation 6) will only decrease the ratio of total active oxygen to O₂.

It is desirable for the present active oxygen source to have conditions that favor (i.e., be configured to favorably select or promote) the formation reaction pathway (first reaction pathway 710 that produces atomic oxygen and second reaction pathway 720 that produces ozone) rather than the loss reaction pathway where ozone forms molecular oxygen, where the loss reaction pathway may involve one or both of the component loss reaction pathways 730 and/or 735.

The rate constants kᵢ for each of the reaction pathways are physically dependent upon one or more of the number density of the associated reaction species, pressure P, temperature T and volume V as well as the photon flux and energy (power level and wavelength of radiation from the optical excitation source).

The Ideal Gas Law may be used to determine the number of initial O₂ reactant species nₒ_{₂} in a reaction chamber having a volume V and temperature T and an initial O₂ pressure P as follows:

$${n}_{{O}_{2}} = \frac{PV}{R T} \qquad ( Equation 7 )$$

where R is the universal gas constant. The total optical absorption cross-section for O₂ may then be determined by the product of nₒ_{₂} with the absorption cross-section per molecule of O₂ available for a particular photon energy. In one example, reaction rate k₁ for first reaction pathway 710 (producing atomic oxygen) depends upon the photon flux, photon energy (e.g., in the VUV energy range) and the absorption cross section of O₂ at the photon energy (e.g., see FIGS. 3A and 3B).

Similarly, k₃ for the competing first loss reaction component pathway 730 depends upon the photon flux, photon energy (e.g., in the VUV energy range) and the absorption cross section of O₃ at the photon energy (e.g., see FIGS. 3A and 3B). As previously discussed, at shorter excitation wavelengths the amount of ozone destruction through photodissociation reduces (e.g., see FIG. 4 showing the absorption selectivity for O₂ versus O₃ at wavelengths of 146 nm, 172 nm, and 193 nm, respectively).

In contrast to k₁ and k₃ which are dependent on photodissociation, reaction rates k₂ and k₄ depend directly on the number densities of the respective molecular species involved in the reaction and their associated interaction cross-sections. For example, a higher reaction chamber pressure at fixed volume can favor an increased number density of reactant O₂.

Solar VUV generation of ozone in the extreme to upper atmosphere (stratosphere) is related to the Chapman cycle involving O₂/N₂ mixtures and is altitude dependent. The Chapman cycle attributed to ozone formation typically has reaction rates for stratospheric gases and solar VUV irradiance in the ranges of:

$$1 {0}^{- 9} \leq {k}_{1} \leq 1 {0}^{- 12} {s}^{- 1}$$

$$1 {0}^{- 27} \leq {k}_{2} \leq 1 {0}^{- 33} {cm}^{6} {molecule}^{- 2} {s}^{- 1}$$

$$1 {0}^{- 6} \leq {k}_{3} \leq 1 {0}^{- 3} {s}^{- 1}$$

$$1 {0}^{- 12} \leq {k}_{4} \leq 1 {0}^{- 15} {cm}^{6} {molecule}^{- 2} {s}^{- 1}$$

Unlike the upper atmosphere, a system and method for generating an active oxygen species in accordance with aspects of the present disclosure may be engineered to operate based on parameters favorable to the generation of active oxygen species including, but not limited to, the use of a relatively pure O₂ source, a reaction chamber having a finite reaction volume and able to operate at a selected chamber pressure, employment of specific excitation wavelengths for the optical excitation source operating at a selected power operable to disassociate molecular oxygen, and the capability to tune the residence time of the gas species in the reaction chamber by selecting an effective leak-rate of effusing species that are emitted from the reaction chamber. The ability to balance these parameters are based on unique insights described in this disclosure.

The fraction β of active oxygen species in the emitted gas mixture from the outlet of the reaction chamber may be defined as:

$$β = \frac{{N}_{A c t i v e} ( {O}^{*} , {O}_{3} )}{{N}_{i} ( {O}_{2} ) + {N}_{A c t i v e} ( {O}^{*} , {O}_{3} )} \qquad ( Equation 8 )$$

where N_{Active}(O*, O₃) is the number density or concentration of the combined atomic oxygen and ozone species and Nᵢ (O₂) is the number density or concentration of molecular O₂ in the gas mixture emitted from the outlet of the reaction chamber.

As would be appreciated, values for β≤0.05 are typically obtained using dielectric barrier discharges and/or plasma excitation employing a pure O₂ feedstock. That is, less than 5% of the gas mixture produced by these approaches comprise the desired active oxygen species. The remaining 95% of the gas mixture comprises neutral molecular oxygen, and in applications such as vacuum deposition this will present a hard limit to typical capacities of associated pumping systems and can cause accelerated degradation of hot surfaces and electrical filaments prone to oxidation.

Embodiments in accordance with the present disclosure are based on the insight that in various applications, such as vacuum deposition of oxide layers, high mass flow rates of ozone are not required, and low flow rates may be desirable for the deposition process.

The above example photoreaction pathways defined in the simultaneous reactions of Equations (3)-(6) may be reduced to the following coupled equations:

$$\frac{d [ {O}^{*} ]}{dt} = 2 {k}_{1} [ {O}_{2} ] - {k}_{2} [ {O}^{*} ] [ {O}_{2} ] + {k}_{3} [ {O}_{3} ] - {k}_{4} [ {O}^{*} ] [ {O}_{3} ] \qquad ( Equation 9 )$$

$$\frac{d [ {O}_{3} ]}{dt} = {k}_{2} [ {O}^{*} ] [ {O}_{2} ] - {k}_{3} [ {O}_{3} ] - {k}_{4} [ {O}^{*} ] [ {O}_{3} ] \qquad ( Equation 10 )$$

In this example, the steady-state output of the reaction chamber is the desired quantity of interest and may be estimated by uniquely recognizing that this will occur when the change in concentration of the ozone and active oxygen components is zero, i.e.:

$$\frac{d [ {O}_{3} ]}{dt} = \frac{d [ {O}^{*} ]}{dt} = 0 \qquad ( Equation 11 )$$

The steady-state concentrations of atomic oxygen [O*]ₛₛ and ozone [O₃]ₛₛ may then be determined as follows:

$${[ {O}^{*} ]}_{s s} = \frac{2 {k}_{1} [ {O}_{2} ] + {k}_{3} [ {O}_{3} ]}{{k}_{2} [ {O}_{2} ] + {k}_{4} [ {O}_{3} ]} \qquad ( Equation 12 )$$

$${[ {O}_{3} ]}_{s s} = \frac{{k}_{2}}{{k}_{4}} \frac{[ {O}_{2} ]}{( 1 + {k}_{3} / {k}_{4} [ {O}^{*} ] )} ≅ \frac{{k}_{2}}{{k}_{3}} [ {O}_{2} ] [ {O}^{*} ] \qquad ( Equation 13 )$$

As is apparent from the equations derived in this disclosure, the ozone concentration is driven by the attachment reaction rate k₂ (see Equation 4) and inversely proportional to the reaction rate k₃ corresponding to the photodissociation of ozone (see Equation 5).

Ranges of values for these steady state concentrations include, but are not limited to:

$$1 {0}^{5} \leq [ {O}^{*} ] \leq 1 {0}^{10} \frac{molecule}{{cm}^{3}}$$

$$1 {0}^{11} \leq [ {O}_{3} ] \leq 1 {0}^{16} \frac{molecule}{{cm}^{3}}$$

These parameters and rates, based on the insights described in this disclosure, may be used as a guide to configure a reaction chamber in accordance with the present disclosure for production of active oxygen species having a required concentration relative to O₂.

For the case of a substantially pressurized chamber of initially pure O₂ composition held at configuration (P₀, V₀, T₀), the rate of change of the [O₂] can be defined for a closed system as:

$$\frac{d [ {O}_{2} ]}{dt} = - {k}_{1} [ {O}_{2} ] - {k}_{2} [ {O}_{2} ] [ {O}^{*} ] + {k}_{3} [ {O}_{3} ] + 2 {k}_{4} [ {O}^{*} ] [ {O}_{3} ] \qquad ( Equation 14 )$$

As discussed above, in various applications a low flow rate is desirable, and so the above Equation 14 forms a good approximation as the gas mixture emitted from the reaction chamber will effectively correspond to a small leak through an outlet that functions as a conductance limiting aperture which may then be coupled to a further deposition chamber.

In other applications, higher “leak” rates (i.e., the flow rate or flux) of the emitted gas mixture that may alter the pressure within the reaction chamber may be balanced by having an active flow of feedstock O₂ into the reaction chamber. However, in these examples, there should be consideration that the residence time of oxygen species within the reaction chamber will be a factor for determining photon absorption probability in the reaction chamber.

The fraction of active oxygen species [O₃]ₛₛ at steady state relative to the overall mixture of species is then given by:

$${β}_{s s} = \frac{{[ {O}_{3} ]}_{s s}}{{[ {O}_{2} ]}_{ss} + {[ {O}_{3} ]}_{s s} + {[ {O}^{*} ]}_{ss}} \qquad ( Equation 15 )$$

This reaction pathway diagram of FIG. 7 demonstrates the complexity in creating conditions for reaction pathways 710 and 720 to occur, for forming atomic oxygen and ozone, respectively, while limiting reaction pathways 730 and 735 from converting the produced ozone back to molecular oxygen before the ozone is emitted from the reaction chamber (i.e., corresponding to the three coupled rate equations of Equations 9, 10 and 14). In other words, generating a stable, and in particular continuous, source of ozone is difficult to achieve and not straightforward without the inventive insights recognized in this disclosure. A stable level of active oxygen species produced may be, for example, a concentration of active oxygen in the output flow stream remaining within (i.e., not fluctuating more than) 10% of an average amount for at least an hour or remaining within 5% of an average amount for at least 10 hours. The active oxygen systems of the present disclosure provide a stabile, point of use source that can produce active oxygen in real time, on demand.

As will be appreciated, reaction pathway diagram 700 is somewhat simplified as the various chemical processes are in equilibrium, meaning that the reaction will be occurring in both directions. For example, for the dissociation of molecular oxygen to atomic oxygen (reaction pathway 710), there will be a reverse reaction where atomic oxygen combines to form molecular oxygen. This reverse reaction, occurring in the opposite direction as the arrow for reaction pathway 710, will also have its own reaction rate. It should also be noted that in a closed system, 100% ozone cannot be obtained due to loss mechanisms. For example, a reaction similar to the reverse reaction of Equation 3 (the reverse of reaction pathway 710), where two atoms of atomic (excited) oxygen combine to form molecular oxygen and energy, could be a significant loss reaction if the concentration of excited atomic oxygen were high enough in the chamber.

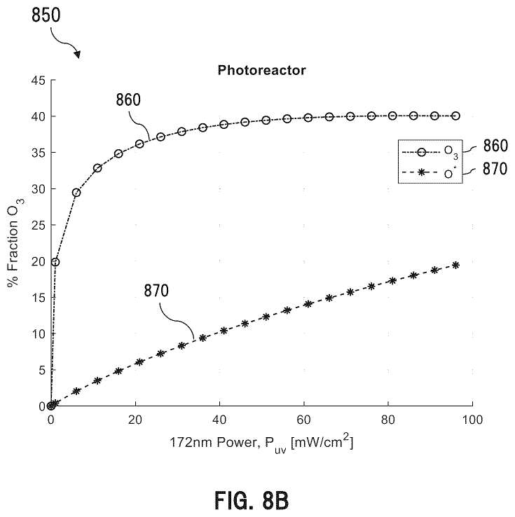

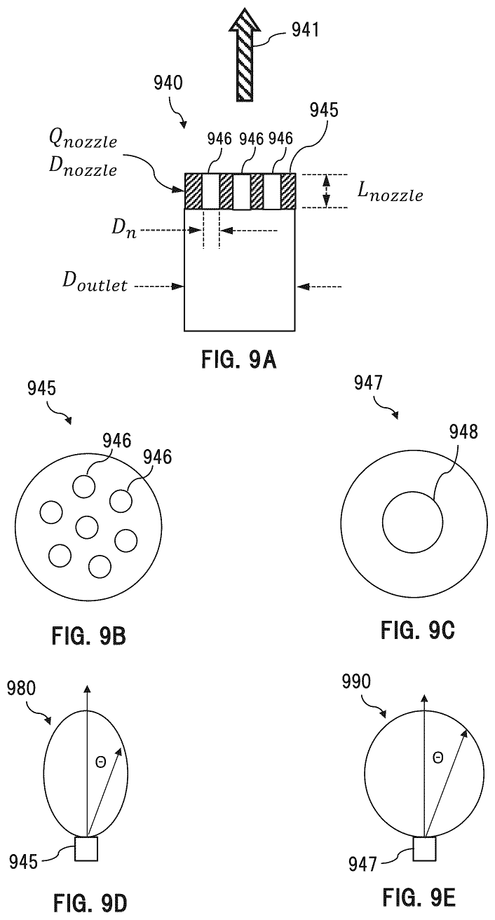

An example of reactions occurring within the reaction chamber is demonstrated in FIG. 8A, using example photoreaction conditions in accordance with the present disclosure. Graph 800 of FIG. 8A shows the evolution of concentrations (expressed in percentages) of molecular oxygen, atomic oxygen and ozone over time (in seconds) in accordance with the reaction pathway diagram 700 of FIG. 7 and coupled rate equations of Equations 9, 10 and 14 in a reaction chamber having a 172 nm excitation source.

In the example represented by graph 800, the excitation source is assumed to be a 50 mW/cm² lamp operating at 172 nm, and the reaction chamber has a volume of 200 cm³ operating at room temperature with an initial oxygen pressure of 100 mTorr. Notably, a reaction chamber operating in accordance with embodiments of the present disclosure will operate at moderate temperatures as compared to the elevated temperatures of a DBD ozone generating arrangement. As can be seen in graph 800, the concentration of molecular oxygen 810 is initially high but rapidly disassociates (in approximately one second) to form atomic oxygen. The concentration of atomic oxygen 820 initially rises and then falls as ozone is formed by the reaction of atomic oxygen and molecular oxygen. In this example, the gas mixture formed in the reaction chamber after an initial establishment period of approximately two seconds has a steady state concentration of ozone 830 approaching 38%, a steady state concentration of atomic oxygen 820 of approximately 7%, and a steady state concentration of molecular oxygen 810 of approximately 55%. These levels of ozone are significantly higher than can be achieved with conventional techniques.

Graph 800 demonstrates that in accordance with the present disclosure, the excitation energy, excitation wavelength, operating pressure, and other factors can be configured to stably produce (e.g., a continuous supply for several seconds, or several minutes, or longer) a gas mixture of molecular oxygen, atomic oxygen, and ozone. The generation of the active oxygen species comprising atomic oxygen and/or ozone is achieved by optical excitation, without the use of a plasma generator (e.g., RF microwave generator or other plasma actuator/plasma source).

Conditions for the reactions must be carefully considered and designed to be able to achieve generation of active oxygen species as described herein (e.g., FIGS. 7 and 8A). For example, the operating pressure and volume of the reaction chamber will determine the number density of oxygen molecules. The lamp output power density at a certain frequency (e.g., number of photons/cm²) will determine the number of photons that can potentially interact with oxygen or ozone molecules having an absorption cross section per unit area. While the above example of FIG. 8A is based on continuous photoexcitation, pulsed photoexcitation is possible and may potentially provide a high peak power photon flux but with an associated duty cycle.

Referring to FIG. 8B, a graph 850 shows the general dependence of the steady state concentration of ozone 860 and steady state concentration of atomic oxygen 870 on the power of the optical excitation source. In this example, for graph 850 the optical excitation source is assumed to be a 172 nm continuous excitation source as has been described earlier. As can be seen, generally the concentration of ozone 860 and atomic oxygen 870 will increase with increasing power of the optical excitation source, with the concentration of ozone 860 beginning to level out at approximately 50 mW/cm² while the concentration of atomic oxygen 870 continues to increase moderately.

As an example, currently high-power VUV sources are limited to approximately 50 mW/cm². As can be seen from FIG. 8B, lower power sources may be employed but this can potentially affect concentrations of the active oxygen species, and furthermore longer integration times may be required in order to reach steady state concentrations. It should be noted that higher power VUV sources may also be readily utilized and may enable even more compact reaction chambers. For example, some embodiments may utilize optical excitation sources with a power intensity of 50 mW/cm² or higher. In principle, very high-power extreme UV (EUV) sources operating at 10-100 nm designed for high performance lithography are available, however, these sources at the present time are not economically practical for the present application.

In other considerations, ozone is a relatively stable molecule compared to atomic oxygen. Interaction of atomic oxygen with the reaction chamber surfaces and/or outlet and/or any nozzle coupled to the outlet may cause atomic oxygen to recombine and as a result reduce its concentration. In one example, the various surfaces with which atomic oxygen may be expected to interact are coated with a high purity silica glass or other oxide type coating. In other examples, an oxide coating is allowed to form on the internal surfaces during operation. As an example, for a reaction chamber formed of aluminum, an aluminum oxide coating may be allowed to form during operation which will beneficially reduce the recombination of atomic oxygen. These configurations may be utilized with any of the systems and methods described herein. As would be appreciated, polymer and plastic materials should generally be avoided in the reaction chamber due to potential contamination caused by carbon, fluorocarbons, and hydrocarbons.

Another potential consideration when using a dielectric barrier excimer lamp as the optical excitation source inside the reaction chamber, is that if the molecular oxygen pressure is within a certain range governed by the Paschen curve, then parasitic discharge may occur in the molecular oxygen in the reaction chamber rather than discharging within the lamp. Having too high of ozone pressure/density within the reaction chamber is also a safety hazard given that ozone is highly reactive. Balancing all these factors is difficult, and the present disclosure provides insights and system designs that can achieve the needed conditions.

It was found empirically in some examples that by reducing the oxygen pressure well below atmospheric pressure of 1 bar (e.g., 100 Torr) in the reaction chamber, an increased concentration of ozone is formed upon excitation of molecular oxygen by an optical excitation source in the ultraviolet wavelength range where there is sufficient residence time in the reaction chamber to allow photon absorption to occur by the rarefied molecular oxygen gas. In some examples, the reaction chamber is configured to sustain a pressure less than approximately 100 Torr, such as between 1-100 Torr, or between 10-100 Torr, or between 1-80 Torr, or less than 10 Torr.

Notably, unlike conventional ozone generators which are directed to maximizing the flow rate (e.g., sterilization applications operating at 100 litres/second), systems and methods of the present disclosure are directed to enhancing the concentration of active oxygen species in the output gas mixture at a low flow rate, for example for operation with deposition systems, such as an ultrahigh vacuum (UHV) deposition system.

In one example, the flow rate of the input molecular oxygen is in the range of 0.1 SCCM to 1000 SCCM. In another example, the flow rate is in the range of 1 SCCM to 100 SCCM. In yet another example, the flow rate is in the range of 1 SCCM to 20 SCCM.

As a consequence of the low flow rate, the present systems result in a longer residence time of a given oxygen molecule in the photoreaction chamber, improving the probability of a photon interaction with the oxygen molecule. In some examples, the residence time can also be improved by incorporating an optical reflector within the photoreactor (e.g., on an interior wall of the reaction chamber) to enhance multipath photon absorption. The optical reflector (i.e., optical resonator) is made of a material to reflect the radiation wavelengths generated by the optical excitation source, such as ultraviolet wavelengths from 125 nm to 180 nm. As an example, the photoreactor of any of the embodiments described herein may be configured with aluminum on some or all of the chamber walls. The optical resonator may be made configured to recycle unabsorbed photons within the gas volume, such as by covering the entire interior walls of the reaction chamber or by inserting plane reflectors along one direction in the longitudinal axis of the chamber. In another embodiment, the inner walls of the chamber may comprise a material composition that reduces the loss of active species on the surface of the chamber walls, for example by using polyrtetrafluoroethylene (PTFE) or fused SiO₂ as a material.

In example configurations of the systems and methods of the present disclosure, conditions include:

A wavelength of the radiation from the optical excitation source of approximately 146 nm, 172 nm, or 193 nm.

An optical input power of the radiation of 10 mW/cm² to 50 mW/cm² to create at least 10-15% atomic oxygen or 10-15% ozone in the exit (output) flow stream at a given flow rate.

A volume of the reaction chamber of 150 cm³ to 250 cm³, such as 200 cm³.

A pressure in the reaction chamber (i.e., operating pressure) of less than 100 Torr (13332 Pascals), such as 1 milliTorr (0.133 Pascals) to 100 Torr or 1 milliTorr to 10 Torr (1333 Pascals).

A flow rate of molecular oxygen being input to the reaction chamber of the active oxygen system of less than or equal to 100 SCCM.

Residence times for the atomic oxygen, the molecular oxygen, and the ozone are on the order of at least several seconds.

These conditions are carefully designed according to the insights described herein to generate active oxygen species. In a specific example, the optical excitation source is a 50 mW/cm² lamp (i.e., average power intensity) operating at 172 nm wavelength (the volume of the reaction chamber of the active oxygen system is approximately 200 cm³, a pressure in the reaction chamber is 100 mTorr (0.133 Pascals) to 1 Torr (133 Pascals), and a flow rate of the input molecular oxygen is 1 SCCM to 10 SCCM. In another example, the optical excitation source is a 10 mW/cm² lamp operating at 146 nm wavelength, the volume of the reaction chamber of the active oxygen system is 200 cm³, the pressure in the reaction chamber of the active oxygen system is 1 Torr to 10 Torr, and the flow rate of the input molecular oxygen is 1 SCCM to 10 SCCM.

In some examples, the active oxygen system is configured to favor (increase the likelihood of) a formation reaction pathway to produce active oxygen species (i.e., atomic oxygen and/or ozone) by photodissociation of molecular oxygen to form atomic oxygen (per first reaction pathway 710, Equation 3), and by reacting molecular oxygen with atomic oxygen to form ozone (per second reaction pathway 720, Equation 4), rather than a loss reaction pathway (e.g., photodissociation of ozone to form molecular oxygen and atomic oxygen per reaction pathway 730, Equation 5; and/or reaction of formed ozone with atomic oxygen to form molecular oxygen per second loss reaction component pathway 735, Equation 6). In some examples, the active oxygen system may have a volume of the reaction chamber configured based on an operating pressure, a wavelength of the radiation, a power of the radiation, and a flow rate of the molecular oxygen into the inlet of the reaction chamber (optionally with other system parameters that affect residence times). In some examples, one or more of an operating pressure, a wavelength of the radiation, a power of the radiation, and a flow rate of the molecular oxygen into the inlet of the reaction chamber (optionally with other system parameters that affect residence times) are configured for a given volume of the reaction chamber. In various examples, the configurations may be set to favorably promote formation of active oxygen species more than loss reaction pathways that create molecular oxygen from ozone and/or atomic oxygen.

In some examples, a volume of the reaction chamber is configured (i.e., set, determined, designed) to provide residence times for the atomic oxygen, the molecular oxygen, and the ozone to favorably select a formation reaction pathway of the molecular oxygen with the atomic oxygen to form the ozone rather than a loss reaction pathway where formed ozone reacts with the atomic oxygen to form the molecular oxygen.

In aspects of the present disclosure, the gas mixture is emitted as a beam containing active oxygen species from an outlet of the reaction chamber (e.g., in block 640 of FIG. 6). For example, as referred to in the description of FIG. 6, the beam that contains active oxygen species may be emitted at a working pressure of between 10₋₅ Torr to 10⁻⁸ Torr for a UHV deposition process such as molecular beam epitaxy (MBE). In some examples, systems and methods may include a nozzle designed to produce a desired pressure differential between the reaction chamber and the receiving chamber (e.g., of a material deposition system). In this manner, the beam profile and outlet working pressure of the photoreactor may be configured in accordance with the deposition process requirements.

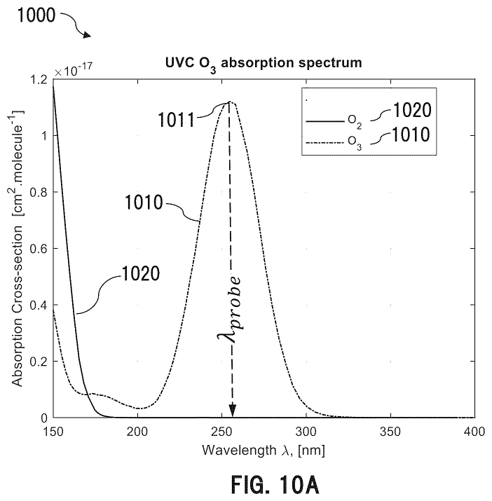

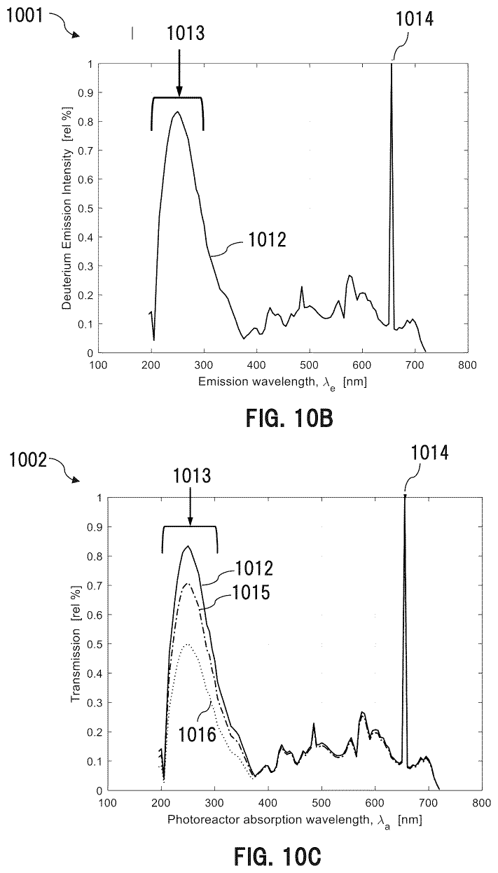

As shown in the side cross-sectional view of FIG. 9A, an outlet 940 may incorporate a beam forming nozzle 945 which is similar to outlet 240 and beam forming nozzle 245 of FIG. 2. In some examples, the nozzle 945 is coupled to the outlet 940 by being attached to the end of or placed inside the outlet 940. Beam forming nozzle 945 has beam profile forming characteristics that primarily depend on a characteristic length of the nozzle in the direction of emission, L_{nozzle}, with a conductance, Q_{nozzle} that is primarily dependent on a characteristic diameter D_{nozzle}. The design of the beam forming nozzle 945 will affect the working pressure and beam profile of the output gas mixture 941.

The photoreactor systems described herein can operate in the molecular or atomic flow regimes. A first function of the beam forming nozzle 945 is to cause a pressure drop. Accordingly, beam forming nozzle 945 has an effective conductance that is determined by the effective aperture having the characteristic diameter D_{nozzle} and the differential pressure across the aperture. The effective aperture may be configured as multiple smaller apertures (each having an associated aperture size) or a single aperture. In this example of FIG. 9A, the beam forming nozzle 945 has multiple apertures 946, each of which has a diameter Dₙ. The characteristic diameter of the aperture, D_{nozzle} can be calculated from the individual diameters Dₙ, combining them in a manner that accounts for losses due to using multiple holes instead of one large hole of equivalent size. The length of the nozzle also affects the conductance of the aperture(s), where the conductance Q_{nozzle} generally reduces with increasing nozzle length L_{nozzle}. In some examples, the nozzle 945 (FIGS. 9A-9C) has an effective aperture diameter D (i.e., D_{nozzle}) and a length L (i.e., L_{nozzle}), wherein an aspect ratio LID is configured to produce a desired pressure differential between the reaction chamber and a receiving chamber; and wherein the beam containing the active oxygen species is delivered through the nozzle, from the outlet 940 to the receiving chamber.

The nozzle 945 may comprise one or more apertures 946, such as 1 to 10, or 2 to 100, or 2 to 500, or up to 1000 individual apertures, each having a diameter Dₙ ranging between, for example, 20 microns to 200 microns that in totality form the characteristic diameter of the aperture, D_{nozzle}. The hole sizes of the apertures 946 are designed to allow the pressure in the reaction chamber to be higher than the downstream system (e.g., a vacuum chamber of a deposition system). In one example, beam forming nozzle 945 may have a characteristic length or thickness L_{nozzle} of 0.5 mm to 1 mm. The plan view of the nozzle 945 in FIG. 9B shows seven apertures 946, as one example. The apertures 946 are shown to be equal in size to each other in FIGS. 9A and 9B, but in other embodiments the apertures 946 may have different sizes from each other.

Referring to FIG. 9C there is shown a plan view of another example beam forming nozzle 947. In this example, beam forming nozzle 947 has a single aperture 948 having an effective diameter equivalent to the combined apertures 946 of beam nozzle 945 shown in FIG. 9B. In this example, both beam forming nozzles 945 and 947 are configured to have the same characteristic length or thickness L_{nozzle}. As a consequence, the aspect ratio LID of the single aperture 948 will be considerably lower than the aspect ratio of the individual apertures 946.

In some examples, the nozzle is configured to provide a cosine n theta flux distribution to the receiving chamber into which the gas mixture is being delivered. For example, the aspect ratio (LID) of the nozzle 945 may be selected to provide an angular flux distribution at some deposition surface at a distance “d” from the aperture plate. This distribution may be generally in the form of a cosine n theta flux distribution with n increasing in line with the aspect ratio (as defined above) to form a more directed beam.

This effect may be seen in FIGS. 9D and 9E which depict figuratively the angular distributions 980 and 990 of the emitted gas mixtures from beam forming nozzles 945 and 947, respectively (side views of the nozzles). As can be seen, the effect of the higher aspect ratio of individual apertures 946 of nozzle 945 results in a more directed angular distribution 980 (i.e., the n is greater in the cosine nθ flux distribution) for the emitted gas mixture from the combination of apertures 946 when compared to the angular distribution 990 of the gas mixture emitted from the single aperture 948 of nozzle 947.

In some examples, the photoreaction chambers of the present disclosure may have an available volume of 200 cm³ to 250 cm³ containing oxygen at an initial pressure of 100 mTorr, and a beam forming nozzle having an effective aperture with a diameter of 1 mm to 10 mm for the supply of active oxygen species to a UHV system operating in the range of 10⁻¹⁰ Torr to 10⁻⁵ Torr.

The generation of active oxygen species (ozone and/or atomic oxygen) may be monitored (e.g., in block 635 of FIG. 6) using a unique probe configuration as shall be described in relation to FIGS. 10A-10E. Although the monitoring system shall be primarily described in terms of monitoring ozone concentration, the system may also be applied to monitoring the concentration of atomic oxygen (instead of or in addition to ozone).

FIG. 10A is a graph 1000 of absorption cross-section (cm²/molecule) as a function of wavelength (nm). Graph 1000 shows an ozone absorption spectrum 1010 in the UVC wavelength range having an absorption peak 1011 at approximately 250 nm. Also shown is a molecular oxygen absorption spectrum 1020 which is negligible for wavelengths greater than 200 nm compared to the ozone absorption spectrum 1010. In some examples, systems and methods beneficially apply insight from graph 1000 by using a probe (monitoring system) operating at a wavelength λ_{probe} that is absorbed by ozone but is not absorbed (or only minimally) by molecular oxygen. As would be appreciated, other probe wavelengths may be used that enable the amount of ozone to be measured and differentiated from molecular oxygen, and/or to monitor the amount of atomic oxygen to be measured and differentiated from molecular oxygen (e.g., using absorption wavelengths for singlet and triplet atomic oxygen).

FIG. 10B is a graph 1001 representing an example of a concentration monitor for ozone in which a deuterium lamp serves as the emission source of the probe wavelength, using a wavelength band around 240 nm. Graph 1001 shows a stabilized deuterium lamp spectrum 1012 in which deuterium emission intensity (in relative percentage to reference peak 1014) is plotted as a function of emission wavelength (nm). As can be seen, the emission intensity is high in a band 1013 centered around 240 nm. The spectrum 1012 has another high intensity peak—reference peak 1014—at around 660 nm. In some examples, systems and methods beneficially utilize insights into these emission characteristics, using deuterium to provide a probe wavelength of approximately 240 nm that will be strongly absorbed by ozone but not molecular oxygen. Some examples also utilize the additional reference peak 1014 as a reference or control peak since this reference wavelength of approximately 660 nm will not be absorbed by ozone. Having a reference wavelength present in the same spectrum as the probe wavelength provides an efficient way to calibrate measurements.

FIG. 10C is a graph 1002 of transmission (in relative percentage to reference peak 1014) as a function of photoreactor absorption wavelength (nm), illustrating measurement of ozone concentration produced in a photoreactor. That is, graph 1002 shows spectra representing different concentrations of ozone in the reaction chamber, detected by a monitoring system having an optical path that passes through the reaction chamber. Deuterium lamp spectrum 1012 is shown as emitted from the probe emission source, having the probe wavelength band 1013 and reference peak 1014 as described for FIG. 10B. Also shown are spectrum 1015 and spectrum 1016 which illustrate detected radiation after passing through the reaction chamber. Spectrum 1015 shows that much of the radiation is still transmitted in the probe wavelength band 1013 around 240 nm, although less than the original lamp spectrum 1012 because some has been absorbed by ozone in the reaction chamber. Spectrum 1015 may represent, for example, 20% ozone concentration in the gas mixture produced in the reaction chamber. Spectrum 1016 has less transmission than spectrum 1015 in the probe wavelength band 1013, which may represent, for example, a higher amount of 50% ozone concentration in the gas mixture produced in the reaction chamber. Both spectra 1015 and 1016 have full transmission of the reference peak 1014, indicating accurate calibration of the measurements.

The ozone concentration monitoring may be substituted by or supplemented with atomic oxygen monitoring by utilizing (or adding) a probe wavelength according to singlet and triplet atomic oxygen absorption lines.

FIG. 10D shows a system overview diagram of a concentration monitoring system 1003 for measuring the concentration of ozone and/or atomic oxygen in the reaction chamber of a photoreactor employing, for example, radiation at the ozone absorption peak 1011 of FIG. 10A or in the band 1013 of FIG. 10B. In FIG. 10D, concentration monitoring system 1003 comprises a narrow band emission source 1030 emitting radiation 1032 having a wavelength of λ_{probe} (e.g., a probe wavelength band near 240 nm to 250 nm per FIGS. 10A-10B, in some examples). The probe radiation 1032 enters reaction chamber 210 through first window 1040 (which may also be referred to as an access window or viewport). The probe radiation 1032 then passes through the gas mixture 1050 comprising molecular oxygen, atomic oxygen, and ozone before exiting through second window 1045 (i.e., access window or viewport). The first and second windows 1040 and 1045 are optically transparent to the probe wavelength λ_{probe} Because λ_{probe} is chosen to be more highly absorbed by ozone and/or atomic oxygen rather than molecular oxygen (e.g., one probe wavelength targeted for ozone and another probe wavelength targeted for atomic oxygen), some of the probe radiation 1032 is absorbed by ozone and/or atomic oxygen in the gas mixture 1050, resulting in an exiting probe beam 1034 which has reduced intensity compared to probe radiation 1032.

Following passage through the reaction chamber 210, the exiting probe beam 1034 is then measured by wavelength selective detector 1060 that operates to measure the intensity of radiation having wavelength of λ_{probe} following any absorption in the reaction chamber 210. The change in intensity of radiation between probe radiation 1032 and the exiting probe beam 1034 will be directly related to the concentration of ozone and/or atomic oxygen in the reaction chamber 210. The concentration of the active species (ozone and/or atomic oxygen) may be determined by a processor 1070 that compares the original probe intensity (probe radiation 1032) to the exiting probe beam 1034. This determined concentration may then be used as feedback to a controller 1072, which may generate a control signal to control parameters (e.g., in block 604 of FIG. 6) such as the flow rate of oxygen entering into reaction chamber 210, the pressure in the reaction chamber 210, and/or the power flux intensity of the excitation source 230a or 230b (shown in FIG. 2). As the flow rate is changed in response to the feedback from the ozone or atomic oxygen concentration monitor, a pressure sensor (e.g., pressure sensor 212 of FIG. 2) may monitor the chamber pressure. For example, both the concentration monitoring system 1003 and the pressure sensor 212 may be used in a feedback loop to control the flow rate, to achieve the desired ozone and/or atomic oxygen concentration level and pressure value in the reaction chamber for favorable conditions to create stable output of an active oxygen species comprising at least one of the atomic oxygen or the ozone (e.g., a gas mixture comprising the atomic oxygen, the molecular oxygen, and the ozone).

In some examples, controller 1072 is configured to control a flow rate of the molecular oxygen into the reaction chamber using a measurement of an ozone concentration or an atomic oxygen concentration in the reaction chamber 210 from a concentration monitor (e.g., concentration monitoring system 1003 in FIG. 10D). The ozone or atomic oxygen concentration monitor is coupled to the reaction chamber, the concentration monitor comprising emission source 1030 configured to emit a probe beam through a first window 1040 in a wall of the reaction chamber, wherein the beam of probe radiation 1032 has a probe wavelength λ_{probe} that is more strongly absorbed by the ozone or the atomic oxygen than by the molecular oxygen. The concentration monitor also includes detector 1060 positioned to receive the probe beam 1034 through a second window 1045 in the wall of the reaction chamber, after passing through the reaction chamber. The probe wavelength (of radiation 1032 of the entering probe beam and radiation of exiting probe beam 1034) for detecting ozone may be from, for example, 200 nm to 300 nm, such as approximately 240 nm or approximately 250 nm, or between 240 nm to 250 nm. Methods may include controlling a flow rate of the molecular oxygen introduced into the reaction chamber, based on an ozone and/or an atomic oxygen concentration in the reaction chamber measured by a concentration monitor. Methods may further include measuring the ozone and/or atomic oxygen concentration by emitting, from emission source 1030, a beam of probe radiation 1032 through a first window 1040 in a wall of the reaction chamber, the probe beam having a probe wavelength that is more strongly absorbed by the ozone or atomic oxygen than by the molecular oxygen; and receiving, by detector 1060, the probe beam 1034 after passing through a second window 1045 in the wall of the reaction chamber.

FIG. 10E is a schematic of a concentration monitoring system 1004, showing details of the detector 1060 in accordance with some embodiments. In this illustration, the probe beam is oriented horizontally rather than vertically as in FIG. 10D. Emission source 1030, such as a deuterium lamp, emits radiation 1032 having a probe wavelength λ_{probe}. The probe radiation 1032 passes through first window 1040 and enters reaction chamber 210 (i.e., photoreactor) where radiation 1055 from an optical excitation source (not shown, e.g., excitation source 230a or 230b of FIG. 2) excites molecular oxygen that is input into the reaction chamber 210 to create gas mixture 1050 comprising molecular oxygen, atomic oxygen, and ozone. The radiation 1055 is shown to be 172 nm wavelength in this illustration but may be other wavelengths as disclosed herein. The probe radiation 1032 then passes through the reaction chamber, being absorbed by ozone or atomic oxygen in the gas mixture 1050. The exiting probe beam 1034, which is reduced in intensity compared to initial radiation 1032, then passes through second window 1045 and enters detector 1060.

Both the first window 1040 and second window 1045 are transmissive to the probe wavelength band. In some examples, the material for first window 1040 and second window 1045 may be chosen such that the windows transmit the probe wavelength band and also absorb the optical excitation wavelength. As a specific example, the material for the ozone concentrator monitor viewports (first window 1040 and second window 1045) may be transmissive to a probe wavelength band around 240 nm and may absorb adjacent optical excitation wavelengths, such as being optically absorptive for wavelengths greater than 200 nm (other than the probe wavelength band around 240 nm). In some examples, the first window 1040 and second window 1045 may be made of sapphire, magnesium oxide, or calcium fluoride.

The detector 1060 includes a diffraction grating 1062. The exiting probe beam 1034 impinges on diffraction grating 1062 and then is directed to a charge-coupled device (CCD) grating spectrometer 1064 which measures the intensity of the exiting probe beam 1034. By comparing the intensity measured by the CCD grating spectrometer 1064 to the known intensity of radiation 1032 generated by the emission source 1030, the ozone and/or atomic oxygen concentration in gas mixture 1050 can be calculated. The CCD grating spectrometer 1064 can also measure the intensity of a reference wavelength (e.g., corresponding to peak 1014 of FIGS. 10A-10B) to calibrate the concentration monitoring system 1004.

In some examples, the concentration of active oxygen species (atomic oxygen and/or ozone) may be monitored using a residual gas monitor or residual gas analyzer (RGA) in a deposition chamber that is coupled to the active oxygen generation system. For example, a residual gas monitor coupled to the interior of a growth chamber to confirm the amount of atomic oxygen, ozone, and/or molecular oxygen that has been received from the active oxygen source. This feedback on the concentration of the various species may be used to control parameters of the active oxygen source, such as the operating pressure, input flow rate of molecular oxygen, or the optical excitation power intensity.

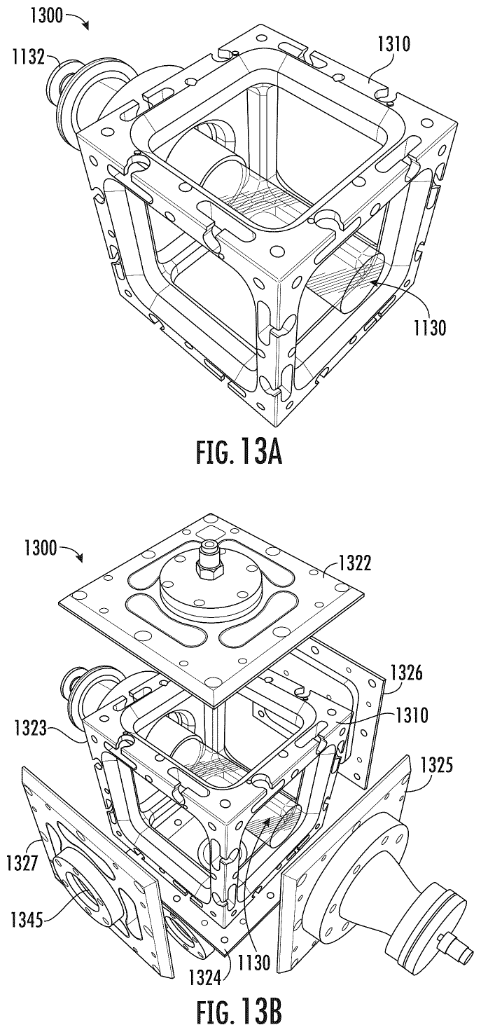

FIG. 11A is a figurative isometric view of a photoreactor 1100 according to an illustrative embodiment. As has been described previously, photoreactor 1100 comprises a reaction chamber 1110 which in this example is configured as a water cooled four-way conflat (CF) cross member 1105 having four apertures arranged at 90 degrees with respect to each other and with associated attachment flanges. The cross member 1105 may include a water-cooled jacket. In this example, left aperture 1112 of cross member 1105 forms an inlet 1120 to introduce input gas 1125 into reaction chamber 1110. Input gas 1125 may be, for example molecular oxygen from an ultra-high pressure O₂ supply. Left aperture 1112 is in fluid communication with right aperture 1114 of reaction chamber 1110, and right aperture 1114 is connected to an outlet 1140. In this example, outlet 1140 is a T-flange member that receives the gas mixture following reaction in the reaction chamber 1110. A pressure sensor 1142 (e.g., a vacuum gauge) is connected to the stem of the T-flange member of the outlet 1140 to monitor the pressure of the outlet gas. A nozzle (not shown, but as described in FIGS. 9A-9C) may be coupled to outlet 1140 for configuring characteristics of the output gas 1150 (e.g., beam containing active oxygen species) emitted by photoreactor 1100.

Attached to top aperture 1113 of reaction chamber 1110 is a cylindrical extension member 1136 configured to receive the optical excitation source 1130. Optical excitation source 1130 is shown as partially inserted into cylindrical extension member 1136, for illustrative purposes. In this example, the optical excitation source 1130 is a commercially available Xenon excimer lamp receivable within a KF50 flange of extension member 1136 so that excimer lamp extends into the central region of reaction chamber 1110. A pumping arrangement 1160 (i.e., a pump) is connected to the bottom aperture 1115, where the pumping arrangement 1160 functions to modify the pressure in the reaction chamber 1110. In this example, photoreactor 1100 also incorporates valving arrangements such as reactor pressure throttle valves 1165 to isolate the various gas flow stages. Measurements from pressure sensor 212 (FIG. 2) and concentration monitoring system 1003 may be used as feedback to control the pumping arrangement 1160, to adjust the pressure in the reaction chamber 1110 (e.g., to compensate for changes in molecular oxygen flow into the chamber and/or gas flow exiting the chamber). For example, one or more of 1) a flow rate of the molecular oxygen, 2) a pump valve to control pressure in the reactor chamber, and 3) a power of the optical excitation source can be controlled based on feedback from the pressure sensor 212 and/or from a concentration monitoring system to achieve a desired concentration level of ozone (and/or atomic oxygen) in the output gas mixture and/or to achieve a desired output pressure of the gas mixture.

In some examples, the volume of the chamber and operating parameters (e.g., chamber pressure, input molecular oxygen flow rate, excitation source wavelength and power) are determined, or at least set to initial levels, prior to operation of the system. In some examples, feedback during operation of the systems and methods is monitored and operating parameters are adjusted manually in response to the feedback. In other examples, a controller comprising a processor is used during operation of the systems and methods to automatically control parameters (e.g., chamber pressure, input molecular oxygen flow rate, excitation source power) based on feedback from measurement sensors such as pressure sensor 212 and the concentration monitoring system.

FIG. 11B is a bottom view of the reaction chamber 1110 illustrated in FIG. 11A, looking upward through the bottom aperture 1115. In this view, the excitation source 1130 can be seen installed in the reaction chamber 1110. FIG. 11B also shows the introduction of molecular oxygen (i.e., input gas 1125) through the left aperture 1112 of reaction chamber 1110 and the emission of a gas mixture (i.e., output gas 1150) comprising atomic oxygen, molecular oxygen and ozone from the right aperture 1114 following reaction in reaction chamber 1110. In this example, the input gas 1125 flow splits to traverse around the excitation source 1130, which is inside the reaction chamber 1110. The traversal around the excitation source 1130 increases the residence time of oxygen particles (i.e., species, molecules) in the reaction chamber 1110 compared to traveling straight through the chamber, to beneficially enable the oxygen molecule reactions of FIG. 7 to occur.

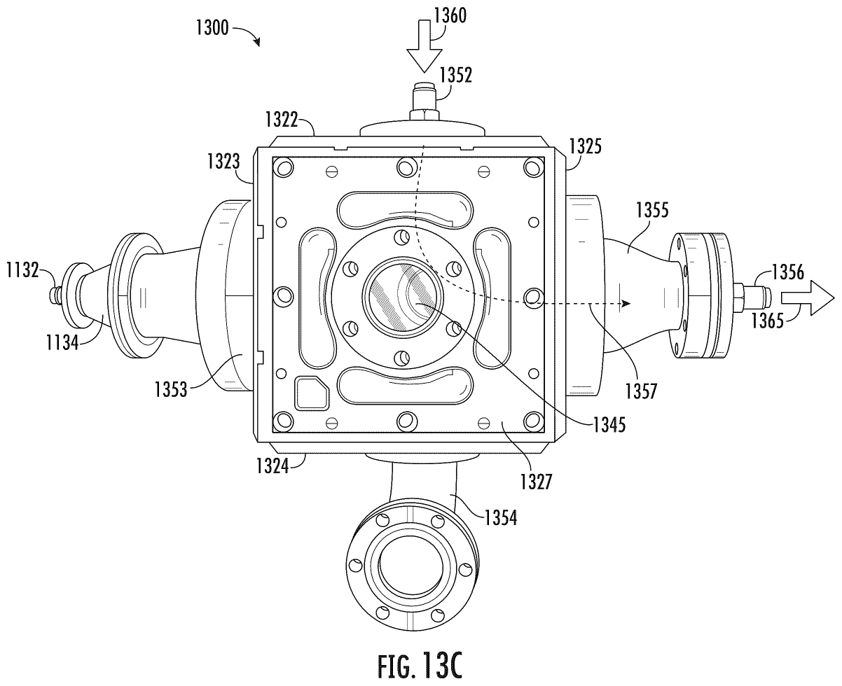

Another example photoreaction chamber is described in relation to FIGS. 12A-12B, 13A-13E, and 14A-14B, where the photoreaction chamber accommodates an ozone concentration monitor (e.g., of FIGS. 10D-10E). FIGS. 12A-12B show front and back perspective views, respectively, of an example of an excitation source 1130. In this example, the excitation source 1130 is an excimer 172 nm lamp that has a lamp portion 1131, a connector 1132 for connecting to a power source for the lamp, and an electronics region 1133 that holds electronics for generating radiation. The lamp portion 1131 is a region from which the produced radiation will be emitted and is configured as a cylinder in this illustration, such as being made of quartz glass. The connection end of excitation source 1130, at an opposite of the excitation source 1130 as the lamp portion 1131, is placed into an adapter 1134 for mounting the lamp to the photoreactor. Adapter 1134 in this example is a KF50, CF 4.5 conical adapter.

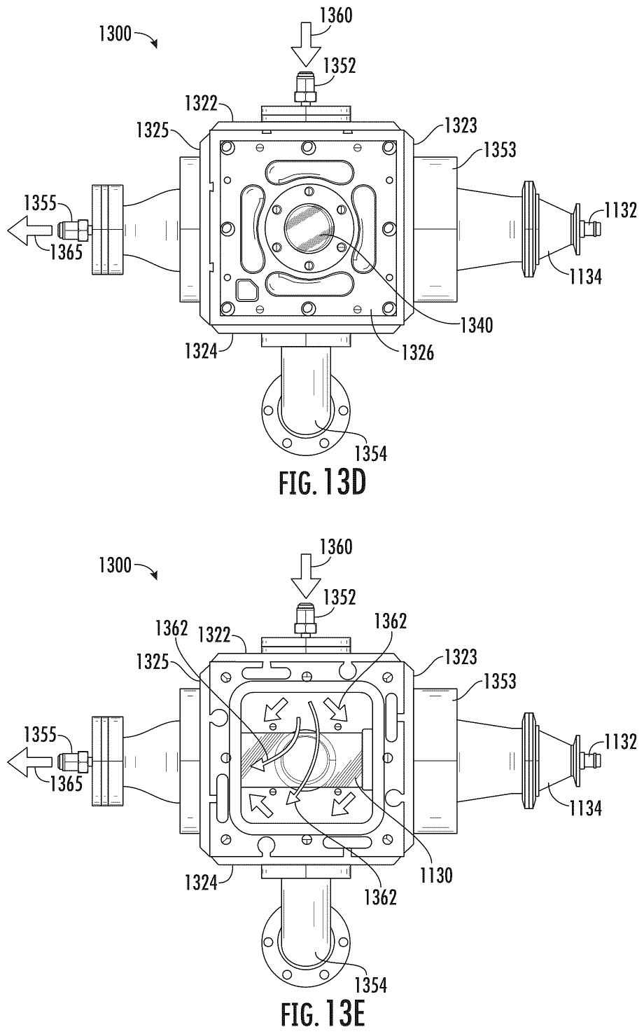

FIG. 13A is a perspective view of a frame 1310 that serves as a supporting structure for a reaction chamber of photoreactor 1300. FIG. 13B is similar to FIG. 13A but with the addition of adapter plates and fittings for the photoreactor 1300, shown as an exploded view. In one example, the frame 1310 may be a 6-inch cube frame. The reaction chamber is the space surrounded by the frame 1310 and plates 1322, 1323, 1324, 1325, 1326 and 1327 (i.e., the space inside the frame and plates). The excitation source 1130 of FIGS. 12A-12B is placed inside frame 1310. Plate 1322 is for the inlet side of the photoreactor 1300 and is configured with fittings to connect to a molecular oxygen input source. Plate 1324, opposite plate 1322, is for connection to a pump (e.g., pumping arrangement 1160) to control the pressure in the reaction chamber. Plate 1323 holds the power source connector end (connector 1132) of the excimer lamp (optical excitation source 1130). Plate 1325 is opposite the plate 1323 and is configured to be the outlet for the gas mixture produced by the photoreactor 1300. Side plates 1326 and 1327 have viewports (i.e., windows) for an ozone concentration monitor to be coupled to. For example, an emission source for emitting a probe wavelength may be coupled to side plate 1326, and a detector for detecting the probe wavelength may be coupled to side plate 1327. Window 1345 in plate 1327 is visible in FIG. 13B. In this example, the emission source is centered in the reaction chamber, but may be offset from the center of the chamber in other examples. Similarly, although the viewports (e.g., window 1345) are shown as centered on the side plates in this example, the viewports may be offset from the center of the chamber in other examples while still providing an optical path for a probe beam to pass through the gas mixture produced in the reaction chamber.

FIG. 13C is an assembled view of the photoreactor 1300 in which the side plate 1327 is shown in front, with the window 1345 that serves as a viewport (e.g., transparent to wavelength bands centered around approximately 240 nm to 250 nm) for the detector of an ozone concentrator monitor. Plate 1322, on the top side of photoreactor 1300 in this view, is configured with inlet 1352 (e.g., a vacuum coupling radius “VCR” connector), for coupling to a molecular oxygen source so that gas flow 1360 of molecular oxygen can be input into the reaction chamber. Plate 1325, on the right side in this illustration, is configured with outlet 1355 to allow the gas mixture 1365 of ozone, atomic oxygen and molecular oxygen to exit the reaction chamber. A nozzle 1356 may be coupled to the outlet 1355 for providing desired beam profile characteristics of the output gas mixture 1365. Nozzle 1356 can also include an aperture or an orifice plate (not shown) as described herein (e.g., aperture 246 in FIG. 2, apertures 946 in FIG. 9B, or aperture 948 in FIG. 9C).

As can be seen in FIG. 13C, flow directions of the inlet 1352 and outlet 1355 are approximately 90 degrees from each other in this example, creating a curved flow path 1357 that involves a bend between the inlet 1352 and the outlet 1355. The curved flow path 1357 is an illustrative representation of the general flow path of gas from the inlet to the outlet. Actual gas molecules in the reaction chamber will likely traverse an even more tortuous path than that shown by flow path 1357, bouncing off the walls of the reaction chamber while reacting with other gas molecules and with photons before exiting through outlet 1355. This non-linear flow path 1357, caused by flow directions of the inlet 1352 and outlet 1355 being oriented at a non-linear angle to each other, beneficially increases the residence time of molecular oxygen in the reaction chamber of photoreactor 1300 compared to a linear path, enhancing the ability for ozone to be formed. In various examples, the reaction chamber can be configured such that the gas flow path between the inlet and the outlet has a bend with an angle greater than or less than 90 degrees, for example, from 30 degrees to 180 degrees. The bend (i.e., curved flow path) may be created by having the inlet 1352 and outlet 1355 located on adjacent walls of the reaction chamber rather than being located on opposite sides of the reaction chamber.

Plate 1323, on the left side in FIG. 13C, has a spacer 1353 in this illustration, to provide proper positioning of the active area of the excitation source (i.e., lamp portion 1131) within the reaction chamber. For example, the active area of the excitation source can be roughly centered within the reaction chamber or can be positioned such that it is roughly in the center of the gas flow path (e.g., so that the gas flows around the excitation source). In one example, the spacer 1353 may be a zero length 4.5″ CF spacer. The connector 1132 of the excitation source and the conical adapter 1134 can be seen extending from plate 1323 and spacer 1353 in this illustration.

An optional elbow tube 1354 is coupled to plate 1324, which can help protect a pressure gauge (not shown, e.g., pressure sensor 212 of FIG. 2) that will be coupled to plate 1324. A pump (e.g., pumping arrangement 1160) that controls the pressure in the reaction chamber is also coupled to plate 1324, such as having the pump connected to the pressure gauge, which is connected to the elbow tube 1354. Vacuum pressure gauges often include a membrane to shield sensitive electronics in the pressure gauges. VUV radiation can cause the membrane to degrade, which can damage the pressure gauge. The elbow tube 1354 can help protect the pressure gauge by removing the sensor (pressure gauge) from the line of sight of the VUV radiation source. Thus, in some examples, photoreactor 1300 may include an elbow tube (or other non-linear conduit) between the pressure gauge (e.g., pressure sensor and associated components) and the excitation source in the reaction chamber.

FIGS. 13D and 13E are views of photoreactor 1300 where the same reference numbers are used as in FIGS. 13A-13C. FIG. 13D is a rear view of FIG. 13C, where side plate 1326 is in front, with a window 1340 that serves as a viewport (e.g., transparent to wavelength bands centered around approximately 240 nm to 250 nm) for an emission source of an ozone concentrator monitor. FIG. 13E is the same view as FIG. 13D but with side plate 1326 removed to show the interior of the reaction chamber. Arrows 1362 represent gas flow paths, demonstrating that the gas flows in a curved path, having to turn approximately 90 degrees from the flow direction orientation of inlet 1352 to the flow direction orientation of outlet 1355 in this example. This curved flow path is created, in this example, by inlet 1352 being located on a first wall that is adjacent to a second wall on which outlet 1355 is located, rather the inlet and outlet than being on walls that are on opposite sides of the reaction chamber which would create a straight flow path across the reaction chamber. In some cases, the flow within the reaction chamber is non-turbulent. The flow path may be further lengthened by the location of the excitation source. For example, when the excitation source 1130 is inside the reaction chamber, the gas must flow around the excitation source 1130, which is a cylinder that extends through the center of the reaction chamber in this example. Creating a non-straight path between the inlet 1352 and outlet 1355 of the reaction chamber, where inlet 1352 and outlet 1355 are oriented in directions that are offset or at a non-linear angle to each other and furthermore where gas molecules must flow around the excitation source, beneficially increases the residence time compared to a straight flow path such that the reactions as explained in FIGS. 7-8B can occur to create atomic oxygen from the excitation of molecular oxygen, and ozone from atomic oxygen and molecular oxygen.

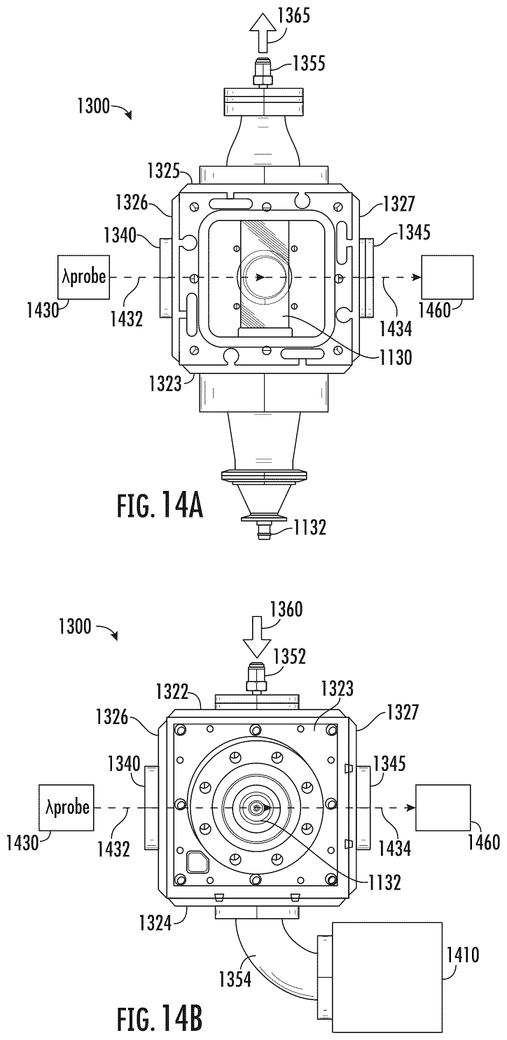

FIGS. 14A and 14B are similar to FIGS. 13A-13E, using the same reference numbers for like elements of photoreactor 1300 but with the views oriented to show components of an ozone concentrator monitor, in accordance with some embodiments. FIG. 14A shows side plate 1326 on the left and side plate 1327 on the right. Window 1340 is coupled to side plate 1326, and window 1345 is coupled to side plate 1327. An ozone concentrator monitor comprises an optical emission source 1430 and a detector 1460. Optical emission source 1430 emits radiation 1432 having a probe wavelength λ_{probe}, and detector 1460 detects exiting radiation 1434 that has passed through the reaction chamber to determine how much radiation has been absorbed by ozone in the reaction chamber. In one example, emission source 1430 emits radiation with a narrow emission band around λ_{probe}, where λ_{probe} is approximately 240 nm. Windows 1340 and 1345 are transparent to the probe wavelength, and the lamp portion of the excitation source 1130 is also transparent to the probe wavelength.

FIG. 14B is similar to FIG. 14A but rotated such that plate 1323 with connector 1132 for the excitation source power connection is facing front. The inlet 1352 for gas flow 1360 is shown on the top side of the photoreactor 1300. Optical emission source 1430 emits radiation 1432 through window 1340, and detector 1460 receives exiting radiation 1434 through window 1345. In this view, a pressure gauge 1410 is shown, coupled to elbow tube 1354 which is coupled to plate 1324. A pump (not shown) will be coupled to the pressure gauge, with the pressure gauge between the pump and the elbow tube 1354.

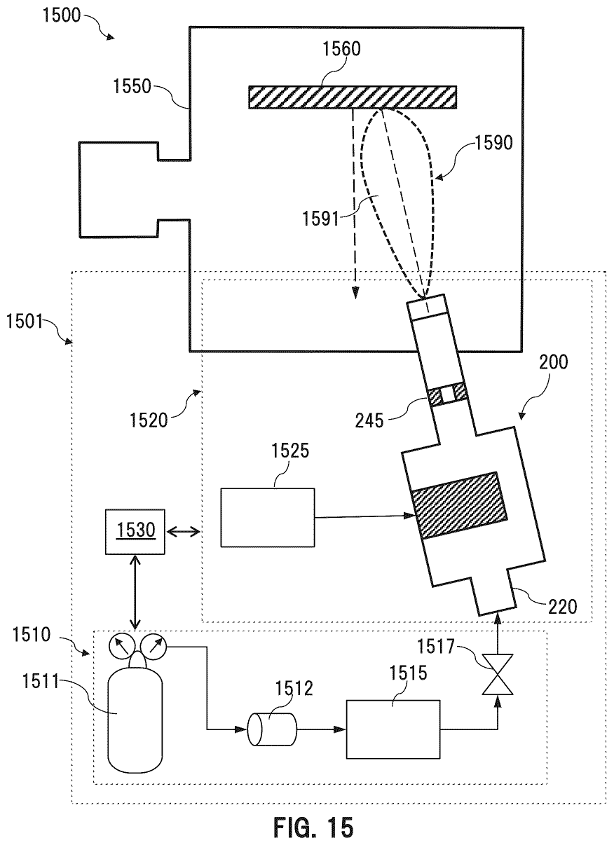

FIG. 15 is a figurative schematic of a system 1500 in which a photoreactor as disclosed herein supplies ozone to a receiving chamber, such as a vacuum deposition chamber or other material deposition chamber (e.g., deposition system). In FIG. 15, system 1500 is a deposition arrangement that incorporates a deposition chamber 1550 (e.g., a vacuum deposition chamber) and an active oxygen species generating system 1501 in accordance with the present disclosure. Vacuum deposition chamber 1550 is configured to deposit material onto a substrate 1560. Active oxygen species generating system 1501 comprises a molecular oxygen source 1510 and a photoreactor system 1520 configured to emit a beam 1590 containing active oxygen species into the deposition chamber 1550 that operates within a pressure range of 10⁻⁴ Torr to 10⁻¹⁰ Torr in one example. In another example, the deposition chamber 1550 operates within a pressure range of 10⁻⁵ Torr to 10⁻⁸ Torr.

In one example of FIG. 15, the molecular oxygen source 1510 comprises a bottled supply 1511 of ultrahigh pressure 7N molecular oxygen. A mass flow controller 1515 is coupled to the oxygen source, i.e., supply 1511. The molecular oxygen from supply 1511 is fed into an optional filter 1512 and through mass flow controller 1515 and an output valve 1517 for supply to the inlet 220 of the photoreactor 200 of photoreactor system 1520. A controller 1530, which comprises a processor, may be in communication with the ozone concentration monitoring system 1525, pressure sensor (e.g., pressure sensor 212 and/or pressure gauge 1410), molecular oxygen source 1510, and/or photoreactor 200. In some examples, the controller 1530 is controller coupled to the oxygen source and configured to control a flow rate of the molecular oxygen into the reaction chamber, using a measurement of an ozone concentration in the reaction chamber from an ozone concentration monitor. In some examples, a pressure sensor is connected to a pump, wherein the pump is coupled to the reaction chamber, and wherein feedback from the pressure sensor to the pump is used to control a pressure in the reaction chamber. In some examples, the system comprises a pump coupled to the reaction chamber, a pressure sensor configured to measure a pressure the reaction chamber, and a controller coupled to the pump and the pressure sensor, wherein the controller is configured to control the pump based on feedback from the pressure sensor to control the pressure in the reaction chamber.

Photoreactor 200 functions to generate beam 1590 of active oxygen species. The active oxygen species comprises at least 5%, or at least 6%, or at least 7%, or at least 10%, or at least 30% ozone and has a predetermined beam profile 1591 with a beam flow rate of 1 SCCM to 5 SCCM and a beam pressure within a range of 10⁻⁵ Torr to 10⁻⁸ Torr for deposition on substrate 1560. The beam profile 1591 may be created by a nozzle 245 as described herein (e.g., for FIGS. 9A-9E), which may include an orifice plate and a beam forming component. The beam 1590 may be supplied on demand to the deposition chamber 1550, such as continuously for several minutes or several hours as needed for the deposition process in deposition chamber 1550. Photoreactor system 1520 may also include an ozone concentration monitoring system 1525 which includes a probe emission source and a detector as described herein (e.g., for FIGS. 10A-10E).

In various examples, the systems disclosed herein (e.g., system 1500) are for generating an active oxygen species, the system comprising a reaction chamber and an inlet to the reaction chamber, the inlet configured to be coupled to an oxygen source that contains molecular oxygen. An optical excitation source optically is coupled to the reaction chamber, the optical excitation source configured to generate radiation in an ultraviolet wavelength range, wherein the radiation is configured to excite a proportion of the molecular oxygen in the reaction chamber, without use of a plasma generator, to form atomic oxygen such that the atomic oxygen is able to react with the molecular oxygen in the reaction chamber to form ozone. An outlet from the reaction chamber is configured to emit a gas mixture comprising the atomic oxygen, the molecular oxygen, and the ozone.

In aspects of the systems, the ultraviolet wavelength range of the radiation generated by the optical excitation source is 125 nm to 180 nm. The optical excitation source may be inside the reaction chamber or may be outside the reaction chamber and optically coupled to the interior of the reaction chamber. The optical excitation source may be, for example, an excimer lamp that emits optical excitation wavelengths as described herein.

In some aspects, one or more of a volume of the reaction chamber, an operating pressure, a wavelength of the radiation, a power intensity of the radiation, and a flow rate of the molecular oxygen into the inlet of the reaction chamber (i.e., at least one of these parameters optionally in combination with one or more of the other parameters) are configured to favorably select a formation reaction pathway for the molecular oxygen to form the atomic oxygen and the ozone, rather than a loss reaction pathway where ozone forms the molecular oxygen.

In some aspects, a volume of the reaction chamber is configured to provide residence times for the atomic oxygen, the molecular oxygen, and the ozone to favorably select a formation reaction pathway (reaction pathways 710 and 720) for the molecular oxygen to form the atomic oxygen and the ozone, rather than a loss reaction pathway (pathway 730 and/or 735) where ozone forms the molecular oxygen; and the volume is configured based on an operating pressure, a wavelength of the radiation, a power intensity of the radiation, and a flow rate of the molecular oxygen into the inlet of the reaction chamber.

In some aspects, one or more of an operating pressure, a wavelength of the radiation, a power intensity of the radiation, and a flow rate of the molecular oxygen into the inlet of the reaction chamber are configured for a given volume of the reaction chamber to provide residence times for the atomic oxygen, the molecular oxygen, and the ozone to favorably select a formation reaction pathway for the molecular oxygen to form the atomic oxygen and the ozone, rather than a loss reaction pathway where ozone forms the molecular oxygen.

In some aspects, a volume of the reaction chamber, an operating pressure, a power intensity of the radiation from the optical excitation source, and a flow rate of the molecular oxygen into the inlet of the reaction chamber are configured to favorably select a formation reaction pathway for the molecular oxygen to form the atomic oxygen and the ozone, rather than a loss reaction pathway where the ozone forms the molecular oxygen. An ultraviolet wavelength range of the radiation generated by the optical excitation source may be 125 nm to 180 nm, such as 146 nm, 172 nm, or 193 nm.

In some aspects, the reaction chamber is configured to sustain a pressure less than 100 Torr (13332 Pascals). In some aspects, the optical excitation source is a 50 mW/cm² source that operates at 172 nm wavelength, the reaction chamber has a volume of 200 cm³, a pressure in the reaction chamber is 100 mTorr (0.133 Pascals) to 1 Torr (133 Pascals), and a flow rate of the molecular oxygen from the oxygen source is 1 SCCM to 10 SCCM.

In some aspects, the systems may include a controller coupled to the oxygen source and configured to control a flow rate of the molecular oxygen into the reaction chamber, using a measurement of an ozone concentration or an atomic oxygen concentration in the reaction chamber from a concentration monitor. The system may include a pump coupled to the reaction chamber and a pressure sensor configured to measure a pressure in the reaction chamber, wherein the controller is coupled to the pump and the pressure sensor, and the controller is configured to control the pump and thereby the pressure in the reaction chamber based on feedback from the pressure sensor.

In some aspects, the systems may include a concentration monitor configured to monitor the atomic oxygen or the ozone, the concentration monitor coupled to the reaction chamber and comprising: an emission source configured to emit a probe beam through a first window in a wall of the reaction chamber, wherein the probe beam has a probe wavelength that is more strongly absorbed by the atomic oxygen or the ozone than by the molecular oxygen; and a detector positioned to receive the probe beam through a second window in the wall of the reaction chamber, after passing through the reaction chamber. The probe wavelength may be, for example, from 200 nm to 300 nm for monitoring ozone.

In some aspects, the gas mixture is emitted as a beam containing the active oxygen species from the reaction chamber, wherein the active oxygen species comprises at least one of the atomic oxygen or the ozone. A nozzle may be coupled to the outlet, the nozzle having an effective aperture diameter D and a length L, wherein an aspect ratio LID is configured to produce a desired pressure differential between the reaction chamber and a receiving chamber; wherein the beam containing the active oxygen species is delivered through the nozzle, from the outlet to the receiving chamber. The receiving chamber may be a vacuum chamber, such as for manufacturing semiconductor materials. The nozzle may be configured to provide a cosine n theta flux distribution. The nozzle may include an orifice plate configured with the effective aperture diameter D; and a beam forming component configured to produce a desired beam distribution.

In some aspects, the systems may include an optical reflector on an interior wall of the reaction chamber. In some aspects, the inlet and the outlet are located on adjacent walls of the reaction chamber to create a curved gas flow path between the inlet and the outlet. In some aspects, the system is for deposition of an oxide film, the system further comprising a material deposition system coupled to the outlet of the reaction chamber to receive the gas mixture comprising the atomic oxygen, the molecular oxygen, and the ozone.

In some aspects of the systems, the ultraviolet wavelength range of the radiation generated by the optical excitation source is 125 nm to 180 nm; and a volume of the reaction chamber, an operating pressure, a power intensity of the radiation from the optical excitation source, and a flow rate of the molecular oxygen into the inlet of the reaction chamber are configured to provide residence times for the atomic oxygen, the molecular oxygen, and the ozone to favorably select a formation reaction pathway for the molecular oxygen to form the atomic oxygen and the ozone, rather than a loss reaction pathway where ozone forms the molecular oxygen.

In some examples, the systems described herein (e.g., FIG. 15, system 1500) may be a system for deposition of an oxide film, where the system comprises a material deposition system (e.g., deposition chamber 1550) and a photoreactor (e.g., photoreactor system 1520). The photoreactor (e.g., photoreactor 200 and embodiments described herein) comprises a reaction chamber, an inlet to the reaction chamber, an optical excitation source, and an outlet from the reaction chamber. The inlet is configured to be coupled to an oxygen source that contains molecular oxygen. The optical excitation source may be inside or outside the reaction chamber, the optical excitation source configured to generate radiation in an ultraviolet wavelength range. The radiation is configured to excite a proportion of the molecular oxygen in the reaction chamber to form atomic oxygen such that the atomic oxygen is able to react with the molecular oxygen in the reaction chamber to form ozone. The outlet is coupled to the material deposition system to deliver a gas mixture comprising the atomic oxygen, the molecular oxygen, and the ozone. Thus, system 1500 may include any of the photoreactors and embodiments thereof described herein, wherein the system is for deposition of an oxide film, the system further comprising a material deposition system coupled to the outlet of the reaction chamber to receive the gas mixture comprising the atomic oxygen, the molecular oxygen, and the ozone.

In some examples, the deposition chamber 1550 may be a material deposition system for forming epitaxial oxides, such as thin films for semiconductor structures. The semiconductor structures may be for devices such as electronic devices or optoelectronic devices. The films may be, for example, binary, ternary or quaternary oxide compositions. In some embodiments, the epitaxial oxides may be metal oxides. For example, the metal oxide may be a ternary metal oxide of the form AₓB₁₋ₓOₙ where 0<x<1.0, where metal specie A may be Al or Ga, and metal specie B may be selected from the group consisting of: Zn, Mg, Ga, Ni, Rare Earth, Ir Bi, and Li. Other examples of oxide materials and structures that may be fabricated with the methods and systems described herein may be those described in U.S. Pat. No. 11,342,484, “Metal Oxide Semiconductor-Based Light Emitting Device”; U.S. Pat. No. 11,502,223, “Epitaxial Oxide Materials, Structures, and Devices”; and U.S. Pat. No. 11,522,103, “Epitaxial Oxide Materials, Structures, and Devices”; all of which are owned by the assignee of the present application and are hereby incorporated by reference in their entirety.

The present disclosure describes a system for generating an active oxygen species, the system comprising a reaction chamber; an inlet to the reaction chamber, the inlet configured to be coupled to an oxygen source that contains molecular oxygen; an optical excitation source optically coupled to the reaction chamber; and an outlet from the reaction chamber. The optical excitation source is configured to generate radiation in an ultraviolet wavelength range, wherein the radiation is configured to excite a proportion of the molecular oxygen in the reaction chamber to form atomic oxygen such that the atomic oxygen is able to react with the molecular oxygen in the reaction chamber to form ozone. The outlet is configured to emit a gas mixture comprising the atomic oxygen, the molecular oxygen, and the ozone.

As can be appreciated, the present methods and systems are operable to provide a point of use supply of active oxygen species which may be generated on demand. In this regard, it shares some similarities with the RF plasma method except that the percentage concentration of active oxygen species generated in accordance with the present disclosure is substantially higher than that generated from any RF plasma-based system.

Components and variations of the embodiments described in the various figures herein can be used in different combinations with each other. For example, any of the photoreactors described herein may utilize either the optical excitation source 230a inside the reaction chamber or the optical excitation source 230b external to the reaction chamber. In another example, the nozzles described in FIG. 2, FIGS. 9A-9C, and elsewhere in this disclosure may be utilized with any of the photoreactors described herein. In another example, an ozone concentration monitor can be utilized with any of the photoreactors described herein. In another example, an active oxygen concentration monitor can be utilized with any of the photoreactors described herein. In other examples, the wavelengths described for the excitation source and the probe wavelengths described for the ozone concentration monitor may be used with any of the photoreactors described herein. Similarly, suitable excitation sources besides the optical excitation source 1130 shown in FIGS. 12A-12B can be utilized, that are compatible with the conditions described herein (e.g., meeting absorption characteristics described in FIGS. 3A-3B). In a further example, the elbow tube 1354 may be used with the photoreactor 1100 or other photoreactors described herein.

In some cases, a single embodiment may, for succinctness and/or to assist in understanding the scope of the disclosure, combine multiple features. It is to be understood that in such a case, these multiple features may be provided separately (in separate embodiments), or in any other suitable combination. Alternatively, where separate features are described in separate embodiments, these separate features may be combined into a single embodiment unless otherwise stated or implied. This also applies to the claims which can be recombined in any combination. That is, a claim may be amended to include a feature defined in any other claim. Furthermore, a phrase referring to “at least one of” a list of items refers to any combination of those items, including single members. As an example, “at least one of: a, b, or c” is intended to cover: a, b, c, a-b, a-c, b-c, and a-b-c.

Reference has been made in detail to embodiments of the disclosed invention, one or more examples of which have been illustrated in the accompanying figures. Each example has been provided by way of explanation of the present technology, not as a limitation of the present technology. In fact, while the specification has been described in detail with respect to specific embodiments of the invention, it will be appreciated that those skilled in the art, upon attaining an understanding of the foregoing, may readily conceive of alterations to, variations of, and equivalents to these embodiments. For instance, features illustrated or described as part of one embodiment may be used with another embodiment to yield a still further embodiment. Thus, it is intended that the present subject matter covers all such modifications and variations within the scope of the appended claims and their equivalents. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only and is not intended to limit the invention.

What is claimed is:

1. A system for generating an active oxygen species, the system comprising:
a reaction chamber;
an inlet to the reaction chamber, the inlet configured to be coupled to an oxygen source that contains molecular oxygen;
an optical excitation source optically coupled to the reaction chamber, the optical excitation source configured to generate radiation in an ultraviolet wavelength range, wherein the radiation is configured to excite a proportion of the molecular oxygen in the reaction chamber, without use of a plasma generator, to form atomic oxygen such that the atomic oxygen is able to react with the molecular oxygen in the reaction chamber to form ozone; and
an outlet from the reaction chamber, the outlet configured to emit a gas mixture comprising the atomic oxygen, the molecular oxygen, and the ozone.

2. The system of claim 1, wherein the ultraviolet wavelength range of the radiation generated by the optical excitation source is 125 nm to 180 nm.

3. The system of claim 1, wherein the optical excitation source is inside the reaction chamber.

4. The system of claim 1, wherein the optical excitation source is an excimer lamp.

5. The system of claim 1, wherein a volume of the reaction chamber is configured to provide residence times for the atomic oxygen, the molecular oxygen, and the ozone to favorably select a formation reaction pathway for the molecular oxygen to form the atomic oxygen and the ozone, rather than a loss reaction pathway where ozone forms the molecular oxygen;
wherein the volume is configured based on an operating pressure, a wavelength of the radiation, a power intensity of the radiation, and a flow rate of the molecular oxygen into the inlet of the reaction chamber.

6. The system of claim 1, wherein one or more of an operating pressure, a wavelength of the radiation, a power intensity of the radiation, and a flow rate of the molecular oxygen into the inlet of the reaction chamber are configured for a given volume of the reaction chamber to provide residence times for the atomic oxygen, the molecular oxygen, and the ozone to favorably select a formation reaction pathway for the molecular oxygen to form the atomic oxygen and the ozone, rather than a loss reaction pathway where the ozone forms the molecular oxygen.

7. The system of claim 1, wherein the optical excitation source is a 50 mW/cm² source that operates at 172 nm wavelength, the reaction chamber has a volume of 200 cm³, a pressure in the reaction chamber is 100 mTorr (0.133 Pascals) to 1 Torr (133 Pascals), and a flow rate of the molecular oxygen from the oxygen source is 1 SCCM to 10 SCCM.

8. The system of claim 1, further comprising a controller coupled to the oxygen source and configured to control a flow rate of the molecular oxygen into the reaction chamber, using a measurement of an ozone concentration or an atomic oxygen concentration in the reaction chamber from a concentration monitor.

9. The system of claim 8, further comprising:
a pump coupled to the reaction chamber; and
a pressure sensor configured to measure a pressure in the reaction chamber;
wherein the controller is coupled to the pump and the pressure sensor, and the controller is configured to control the pump and thereby the pressure in the reaction chamber based on feedback from the pressure sensor.

10. The system of claim 1, further comprising a concentration monitor configured to monitor the atomic oxygen or the ozone, the concentration monitor coupled to the reaction chamber and comprising:
an emission source configured to emit a probe beam through a first window in a wall of the reaction chamber, wherein the probe beam has a probe wavelength that is more strongly absorbed by the atomic oxygen or the ozone than by the molecular oxygen; and
a detector positioned to receive the probe beam through a second window in the wall of the reaction chamber, after passing through the reaction chamber.

11. The system of claim 10, wherein the probe wavelength is from 200 nm to 300 nm.

12. The system of claim 1, wherein the gas mixture is emitted as a beam containing the active oxygen species from the reaction chamber, wherein the active oxygen species comprises at least one of the atomic oxygen or the ozone.

13. The system of claim 12, further comprising a nozzle coupled to the outlet, the nozzle having an effective aperture diameter D and a length L, wherein an aspect ratio LID is configured to produce a desired pressure differential between the reaction chamber and a receiving chamber;
wherein the beam containing the active oxygen species is delivered through the nozzle, from the outlet to the receiving chamber.

14. The system of claim 13, wherein the receiving chamber is a vacuum chamber for manufacturing semiconductor materials.

15. The system of claim 13, wherein the nozzle is configured to provide a cosine n theta flux distribution.

16. The system of claim 13, wherein the nozzle comprises:
an orifice plate configured with the effective aperture diameter D; and
a beam forming component configured to produce a desired beam distribution.

17. The system of claim 1, further comprising an optical reflector on an interior wall of the reaction chamber.

18. The system of claim 1, wherein the inlet and the outlet are located on adjacent walls of the reaction chamber to create a curved gas flow path between the inlet and the outlet.

19. The system of claim 1, wherein the system is for deposition of an oxide film, the system further comprising a material deposition system coupled to the outlet of the reaction chamber to receive the gas mixture comprising the atomic oxygen, the molecular oxygen, and the ozone.

20. The system of claim 1, wherein the ultraviolet wavelength range of the radiation generated by the optical excitation source is 125 nm to 180 nm; and
wherein a volume of the reaction chamber, an operating pressure, a power intensity of the radiation from the optical excitation source, and a flow rate of the molecular oxygen into the inlet of the reaction chamber are configured to favorably select a formation reaction pathway for the molecular oxygen to form the atomic oxygen and the ozone, rather than a loss reaction pathway where the ozone forms the molecular oxygen.
